(19) United States
(12) Patent Application Publication
(10) Pub. No.: US 2023/0231078 A1
(43) Pub. Date: Jul. 20, 2023

(54) DISPLAY DEVICE AND METHOD OF MANUFACTURING THE SAME

(71) Applicant: Samsung Display Co., LTD., Yongin-si (KR)

(72) Inventors: Myeong Su SO, Seoul (KR); Myeong Hee KIM, Yongin-si (KR); Seul Ki KIM, Gwangmyeong-si (KR)

(73) Assignee: Samsung Display Co., LTD., Yongin-si (KR)

(21) Appl. No.: 17/940,091

(22) Filed: Sep. 8, 2022

(30) Foreign Application Priority Data
Jan. 20, 2022 (KR) 10-2022-0008382

(51) Int. Cl. H01L 33/38; H01L 33/62; H01L 33/00

(52) U.S. Cl. CPC H01L 33/382; H01L 33/005; H01L 33/62; H01L 2933/0016; H01L 2933/0066

(57) ABSTRACT

A display device includes a first electrode and a second electrode that are disposed on a substrate to be spaced apart from each other, a first insulating layer disposed on the first electrode and the second electrode, a light emitting element disposed on the first insulating layer, a first connection electrode in electrical contact with a first end of the light emitting element on the first insulating layer, and an organic layer disposed on the first connection electrode and surrounding the light emitting element.

### CROSS-REFERENCE TO RELATED APPLICATION(S)

This application claims priority to and benefits of Korean Patent Application No. 10-2022-0008382 under 35 U.S.C. 119, filed on Jan. 20, 2022 in the Korean Intellectual Property Office, the entire contents of which are herein incorporated by reference.

### BACKGROUND

### 1. Technical Field

The disclosure relates to a display device and a method of manufacturing the same.

### 2. Description of the Related Art

As information society develops, the demand for a display device for displaying an image is increasing in various forms. The display device may be a flat panel display, such as a liquid crystal display, a field emission display, or a light emitting display panel. A light emitting display device may include an organic light emitting display device including an organic light emitting diode element as a light emitting element, an inorganic light emitting display device including an inorganic semiconductor element as a light emitting element, or a micro light emitting display device including a micro light emitting diode element as a light emitting element.

### SUMMARY

Aspects of the disclosure provide a display device capable of preventing shorting of light emitting elements even if the light emitting elements are clustered or disposed to be biased to a side in a pixel, and a method of manufacturing the same.

However, aspects of the disclosure are not restricted to those set forth herein. The above and other aspects of the disclosure will become more apparent to one of ordinary skill in the art to which the disclosure pertains by referencing the detailed description of the disclosure given below.

According to an embodiment of the disclosure, a display device may include a first electrode and a second electrode that are disposed on a substrate to be spaced apart from each other, a first insulating layer disposed on the first electrode and the second electrode, a light emitting element disposed on the first insulating layer, a first connection electrode in electrical contact with a first end of the light emitting element on the first insulating layer, and an organic layer disposed on the first connection electrode and surrounding the light emitting element.

In an embodiment, a top surface of the organic layer and a top surface of the first connection electrode may be flat to each other.

In an embodiment, a portion of a top surface of the light emitting element may protrude from a surface of the organic layer.

In an embodiment, the first connection electrode may not be disposed on a top surface of the light emitting element.

In an embodiment, a height of the organic layer may be greater than a diameter of the light emitting element, and a height of the organic layer may be smaller than about 1.5 times the diameter of the light emitting element.

In an embodiment, a height of the organic layer is in a range of about 500 nm to about 825 nm.

In an embodiment, the organic layer may include a light-transmissive organic material.

In an embodiment, the light emitting element may include semiconductor layers, a light emitting layer disposed between the semiconductor layers, and an element insulating layer partially surrounding outer side surfaces of the semiconductor layers and the light emitting layer, and the element insulating layer may expose a surface of the light emitting layer.

In an embodiment, the display device may further include a second insulating layer disposed on the light emitting element and the organic layer. The second insulating layer may be in physical contact with the light emitting layer.

In an embodiment, the first connection electrode may be electrically connected to the first electrode through a contact portion, and the organic layer may be disposed to cover the contact portion.

In an embodiment, the organic layer may include a portion disposed on the contact portion and another portion surrounding the light emitting element, and the portion and the another portion may be spaced apart from each other with a bank layer interposed therebetween.

In an embodiment, the light emitting element may have a second end opposite the first end, the second end may be in electrical contact with a second connection electrode disposed on the first insulating layer, and a top surface of the second connection electrode and a top surface of the organic layer are flat to each other.

In an embodiment, the display device may further include a passivation layer disposed to cover the first connection electrode. The first connection electrode may be electrically connected to the first electrode through a contact portion.

According to an embodiment of the disclosure, a method of manufacturing a display device may include aligning a light emitting element on a first electrode and a second electrode spaced apart from each other on a substrate, at least partially exposing semiconductor layers of the light emitting element, forming connection electrodes on the light emitting element, forming an organic layer on the light emitting element and the connection electrodes, and etching a portion of the connection electrodes on which the organic layer may not be disposed.

In an embodiment, the forming of the organic layer may include forming an organic material layer covering the light emitting element and the connection electrodes, and heat-treating and planarizing the organic material layer.

In an embodiment, a height of the organic layer may be formed lower than a height of exposed top surfaces of the semiconductor layers.

In an embodiment, the at least partially exposing of the semiconductor layers of the light emitting element may include forming an insulating material layer on the light emitting element, and etching the insulating material layer to form an insulating layer.

In an embodiment, the etching of the connection electrode may be performed to etch the connection electrode disposed on the exposed semiconductor layers of the light emitting element among the connection electrodes.

In an embodiment, the method may further include forming an insulating layer on the connection electrodes and the light emitting element. The insulating layer may be disposed to be in physical contact with the exposed semiconductor layers of the light emitting element.

In an embodiment, the method may further include, before the forming of the organic layer, forming a passivation layer disposed to cover a contact portion connecting the connection electrodes and a voltage line.

According to a display device and a method of manufacturing the same according to embodiments, it may be possible to prevent the light emitting elements from being electrically shorted even if the light emitting elements are clustered or disposed to be biased to a side in the pixel. Accordingly, a dark spot of the display device may be reduced.

However, the effects of the embodiments are not restricted to the one set forth herein. The above and other effects of the embodiments will become more apparent to one of ordinary skill in the art to which the embodiments pertain by referencing the claims.

### BRIEF DESCRIPTION OF THE DRAWINGS

The above and other aspects and features of the present disclosure will become more apparent by describing in detail embodiments thereof with reference to the attached drawings, in which:

FIG. 1 is a schematic plan view of a display device according to an embodiment;

FIG. 2 is a schematic plan view illustrating a pixel of the display device according to an embodiment;

FIG. 3 is a schematic plan view illustrating a sub-pixel of the display device according to an embodiment;

FIG. 4 is a schematic cross-sectional view taken along line E1-E1′ of FIG. 2;

FIG. 5 is a schematic cross-sectional view taken along lines E2-E2′, E4-E4′, and E5-E5′ of FIG. 3;

FIG. 6 is a schematic view of a light emitting element according to an embodiment;

FIG. 7 is an enlarged schematic cross-sectional view of areas X1 and X2 of FIG. 5;

FIGS. 8 to 15 are schematic cross-sectional views illustrating a method of manufacturing a display device according to an embodiment;

FIG. 16 is a schematic cross-sectional view taken along lines E3-E3′, E4-E4′, and E5-E5′ of FIG. 3;

FIG. 17 is an enlarged schematic cross-sectional view of areas X3 and X4 of FIG. 16;

FIG. 18 is a schematic plan view illustrating a sub-pixel of a display device according to another embodiment;

FIG. 19 is a schematic cross-sectional view taken along lines E6-E6′ and E7-E7′ of FIG. 18;

FIG. 20 is an enlarged schematic cross-sectional view of areas X5 and X6 of FIG. 18; and

FIGS. 21 to 24 are schematic cross-sectional views illustrating a method of manufacturing a display device according to another embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, sizes, thicknesses, ratios, and dimensions of the elements may be exaggerated for ease of description and for clarity. Like numbers refer to like elements throughout.

As used herein, the singular forms, “a,” “an,” and “the” are intended to include the plural forms as well, unless the context clearly indicates otherwise.

It will also be understood that when a layer is referred to as being “on” another layer or substrate, it can be directly on the other layer or substrate, or intervening layers may also be present.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

Each of the features of the various embodiments of the disclosure may be combined or combined with each other, in part or in whole, and technically various interlocking and driving are possible. Each embodiment may be implemented independently of each other or may be implemented together in an association.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

It will be understood that the terms “connected to” or “coupled to” may include a physical or electrical connection or coupling.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ± 30%, 20%, 10%, 5% of the stated value.

Unless otherwise defined, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

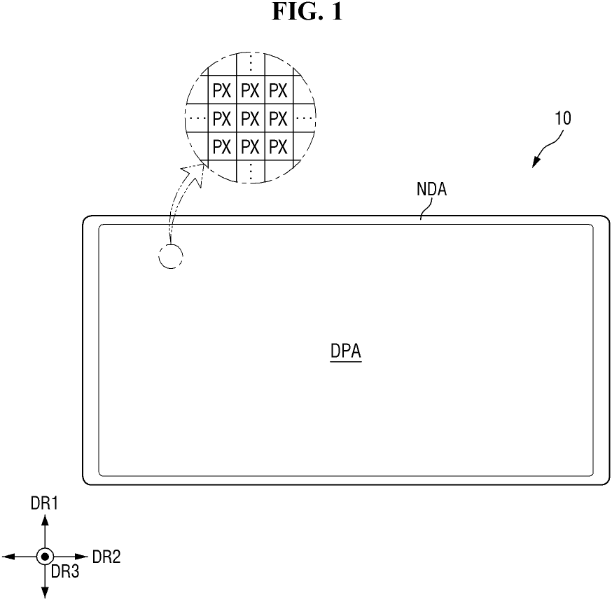

FIG. 1 is a schematic plan view of a display device according to an embodiment.

Referring to FIG. 1, a display device 10 may display a moving image or a still image. The display device 10 may refer to all electronic devices that provide display screens. For example, televisions, laptop computers, monitors, billboards, the Internet of Things (IoT), mobile phones, smartphones, tablet personal computers (PCs), electronic watches, smartwatches, watch phones, head mounted displays, mobile communication terminals, electronic organizers, electronic books, portable multimedia players (PMPs), navigation devices, game machines, digital cameras, camcorders, and the like, that provide display screens may be included as the display device 10.

The display device 10 may include a display panel providing a display screen. Examples of the display panel may include an inorganic light emitting diode display panel, an organic light emitting display panel, a quantum dot light emitting display panel, a plasma display panel, a field emission display panel, and the like. Hereinafter, a case where the inorganic light emitting diode display panel is applied as an example of the display panel will be described by way of example, but the disclosure is not limited thereto, and the same technical idea may be applied to other display panels if applicable.

A shape of the display device 10 may be variously changed. For example, the display device 10 may have a shape such as a rectangle with a long width, a rectangle with a long length, a square, a quadrangle with rounded corners (vertices), other polygons, or a circle. A shape of a display area DPA of the display device 10 may also be similar to an overall shape of the display device 10. In FIG. 1, the display device 10 having a rectangular shape with a long length in a second direction DR2 is illustrated.

The display device 10 may include a display area DPA and a non-display area NDA. The display area DPA may be an area in which a screen may be displayed, and the non-display area NDA may be an area in which a screen may not be displayed. The display area DPA may also be referred to as an active area, and the non-display area NDA may also be referred to as a non-active area. The display area DPA may substantially occupy the center of the display device 10.

The display area DPA may include pixels PX. The pixels PX may be arranged in a matrix direction. A shape of each pixel PX may be a rectangular shape or a square shape in plan view, but is not limited thereto, and may also be a rhombic shape of which each side may be inclined with respect to a direction. Each pixel PX may be arranged in a stripe type or an island type. Each of the pixels PX may include one or more light emitting elements that emit light of a specific wavelength band to display a specific color.

The non-display area NDA may be disposed around the display area DPA. The non-display area NDA may completely or partially surround the display area DPA. The display area DPA may have a square shape, and the non-display area NDA may be disposed adjacent to four sides of the display area DPA. The non-display area NDA may constitute a bezel of the display device 10. Lines or circuit drivers included in the display device 10 may be disposed in each of the non-display areas NDA, or external devices may be mounted thereon.

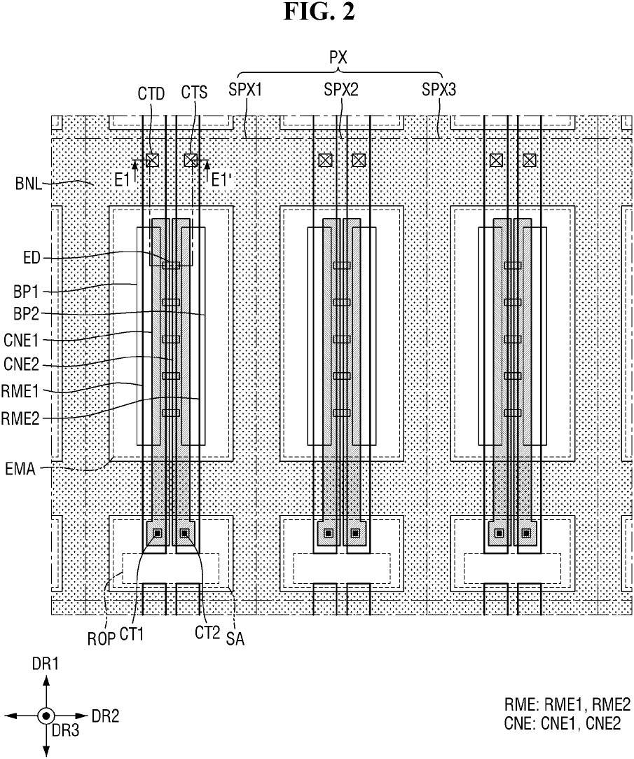

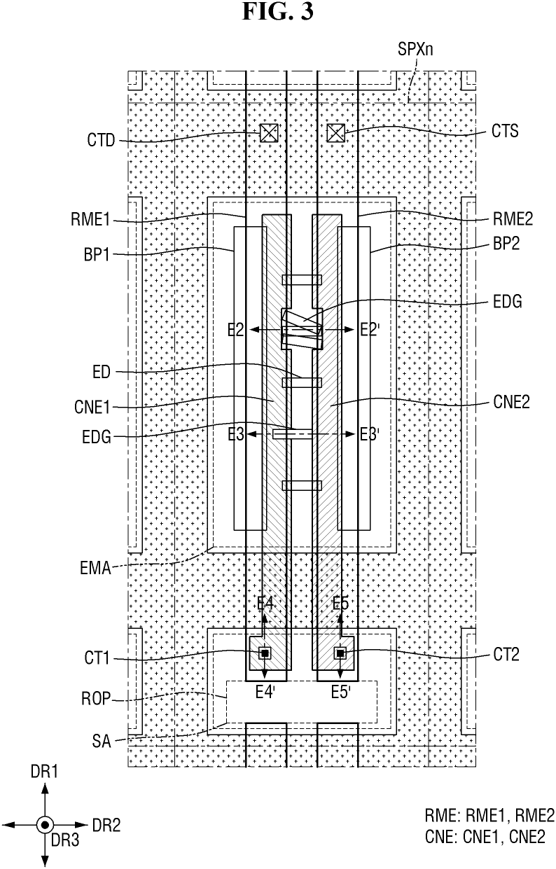

FIG. 2 is a schematic plan view illustrating a pixel of the display device according to an embodiment. FIG. 3 is a schematic plan view illustrating a sub-pixel of the display device according to an embodiment.

FIG. 2 illustrates a planar arrangement of electrodes RME (RME1 and RME2), bank patterns BP1 and BP2, a bank layer BNL, light emitting elements ED, and connection electrodes CNE (CNE1 and CNE2) disposed in a pixel PX of the display device 10. FIG. 3 further illustrates a planar arrangement of light emitting element groups EDG disposed in a sub-pixel SPXn in the pixel PX. In an embodiment, the light emitting element ED may refer to a normal light emitting element, and the light emitting element group EDG may refer to an abnormal light emitting element in which the light emitting elements ED are clustered or disposed to be biased to a side.

Referring to FIGS. 2 and 3, each of the pixels PX of the display device 10 may include sub-pixels SPXn. For example, one pixel PX may include a first sub-pixel SPX1, a second sub-pixel SPX2, and a third sub-pixel SPX3. The first sub-pixel SPX1 may emit light of a first color, the second sub-pixel SPX2 may emit light of a second color, and the third sub-pixel SPX3 may emit light of a third color. As an example, the first color may be blue, the second color may be green, and the third color may be red. However, the disclosure is not limited thereto, and the respective sub-pixels SPXn may also emit light of the same color. In an embodiment, the respective sub-pixels SPXn may emit light of blue. It has been illustrated in FIG. 2 that a pixel PX includes three sub-pixels SPXn, but the disclosure is not limited thereto, and the pixel PX may include a larger number of sub-pixels SPXn.

Each of the sub-pixels SPXn of the display device 10 may include an emission area EMA and a non-emission area. The emission area EMA may be an area in which the light emitting element ED may be disposed to emit light of a specific wavelength band. The non-emission area may be an area in which the light emitting element ED may not be disposed and the light emitted from the light emitting element ED may not reach and may not be emitted.

The emission area EMA may include an area in which the light emitting element ED may be disposed and an area adjacent to the light emitting element ED, from which light emitted from the light emitting element ED may be emitted. For example, the emission area EMA may also include an area in which the light emitted from the light emitting element ED may be reflected or refracted by other members and then emitted. Light emitting elements ED may be disposed in each sub-pixel SPXn, and the emission area including an area in which the light emitting elements ED may be disposed and an area adjacent to the light emitting elements ED may be formed.

It has been illustrated in FIG. 2 that the emission areas EMA of each sub-pixel SPXn have a uniform area, but the disclosure is not limited thereto. In some embodiments, each of the emission areas EMA of each sub-pixel SPXn may have a different area according to a color or wavelength band of light emitted from the light emitting element ED disposed in the corresponding sub-pixel.

Each sub-pixel SPXn may further include a sub-area SA disposed in the non-emission area. The sub-area SA of the corresponding sub-pixel SPXn may be disposed on a lower side of the emission area EMA, which may be another side of the emission area EMA in a first direction DR1. The emission area EMA and the sub-area SA may be alternately arranged along the first direction DR1, and the sub-area SA may be disposed between the emission areas EMA of different sub-pixels SPXn spaced apart from each other in the first direction DR1. For example, the emission area EMA and the sub-area SA may be alternately arranged in the first direction DR1, and each of the emission area EMA and the sub-area SA may be repeatedly arranged in the second direction DR2. However, the disclosure is not limited thereto, and the emission areas EMA and the sub-areas SA of the pixels PX may also have an arrangement different from that of FIG. 2.

Since the light emitting element ED may not be disposed in the sub-area SA, the light may not be emitted from the sub-area SA, but a portion of an electrode RME disposed in each sub-pixel SPXn may be disposed in the sub-area SA. The electrodes RME disposed in different sub-pixels SPXn may be disposed to be separated from each other based on a separation portion ROP of the sub-area SA.

The display device 10 may include electrodes RME (RME1 and RME2), bank patterns BP1 and BP2, a bank layer BNL, light emitting elements ED, light emitting element groups EDG, and connection electrodes CNE (CNE1 and CNE2).

The bank patterns BP1 and BP2 may be disposed in the emission area EMA of each sub-pixel SPXn. The bank patterns BP1 and BP2 may have a shape having a width in the second direction DR2 and extending in the first direction DR1.

For example, the bank patterns BP1 and BP2 may include a first bank pattern BP1 and a second bank pattern BP2 spaced apart from each other in the second direction DR2 in the emission area EMA of each sub-pixel SPXn. The first bank pattern BP1 may be disposed on the left side, which may be a side in the second direction DR2, from the center of the emission area EMA, and the second bank pattern BP2 may be spaced apart from the first bank pattern BP1 and disposed on the right side, which may be another side in the second direction DR2, from the center of the emission area EMA. The first bank patterns BP1 and the second bank patterns BP2 may be alternately disposed along the second direction DR2 and may be disposed in an island-shaped pattern in the display area DPA. The light emitting elements ED and the light emitting element groups EDG may be disposed between the first bank pattern BP1 and the second bank pattern BP2.

Lengths of the first bank pattern BP1 and the second bank pattern BP2 in the first direction DR1 may be the same as each other, but may be smaller than a length of the emission area EMA surrounded by the bank layer BNL in the first direction DR1. The first bank pattern BP1 and the second bank pattern BP2 may be spaced apart from a portion of the bank layer BNL extending in the second direction DR2. However, the disclosure is not limited thereto, and the bank patterns BP1 and BP2 may also be integrated with the bank layer BNL or partially overlap a portion of the bank layer BNL extending in the second direction DR2. In this case, the lengths of the bank patterns BP1 and BP2 in the first direction DR1 may be equal to or greater than the length of the emission area EMA surrounded by the bank layer BNL in the first direction DR1.

The first bank pattern BP1 and the second bank pattern BP2 may have the same width in the second direction DR2. However, the disclosure is not limited thereto, and the first bank pattern BP1 and the second bank pattern BP2 may also have different widths. For example, one bank pattern may have a larger width than another bank pattern, and the bank pattern having the larger width may be disposed across the emission areas EMA of other sub-pixels SPXn adjacent in the second direction DR2. In this case, the bank pattern disposed across the emission areas EMA may overlap a portion of the bank layer BNL extending in the first direction DR1. It has been illustrated in FIG. 2 that two bank patterns BP1 and BP2 having the same width are disposed in each sub-pixel SPXn, but the disclosure is not limited thereto. The number and shape of the bank patterns BP1 and BP2 may vary according to the number or arrangement structure of the electrodes RME.

The electrodes RME (RME1 and RME2) may be disposed in each sub-pixel SPXn in a shape extending in a direction. The electrodes RME1 and RME2 may extend in the first direction DR1 to be disposed in the emission area EMA and the sub-area SA of the sub-pixel SPXn, and may be disposed to be spaced apart from each other in the second direction DR2. The electrodes RME may be electrically connected to a light emitting element ED to be described later. However, the disclosure is not limited thereto, and the electrodes RME may not be electrically connected to the light emitting element ED.

The display device 10 may include a first electrode RME1 and a second electrode RME2 disposed in each sub-pixel SPXn. The first electrode RME1 may be disposed on the left side of the center of the emission area EMA, and the second electrode RME2 may be spaced apart from the first electrode RME1 in the second direction DR2 and may be disposed on the right side of the center of the emission area EMA. The first electrode RME1 may be disposed on the first bank pattern BP1, and the second electrode RME2 may be disposed on the second bank pattern BP2. The first electrode RME1 and the second electrode RME2 may be partially disposed in the corresponding sub-pixel SPXn and the sub-area SA beyond the bank layer BNL. The first electrode RME1 and the second electrode RME2 of different sub-pixels SPXn may be spaced apart from each other based on the separation portion ROP positioned in the sub-area SA of any one sub-pixel SPXn.

It has been illustrated in the drawings that the two electrodes RME have a shape extending in the first direction DR1 for each sub-pixel SPXn, but the disclosure is not limited thereto. For example, in the display device 10, a larger number of electrodes RME may be disposed in one sub-pixel SPXn, or the electrodes RME may also have a shape in which they are partially bent and have different widths according to positions thereof.

The bank layer BNL may be disposed to surround the sub-pixels SPXn, and the emission areas EMA and the sub-areas SA. The bank layer BNL may be disposed at a boundary between the sub-pixels SPXn adjacent in the first direction DR1 and the second direction DR2, and may also be disposed at a boundary between the emission area EMA and the sub-area SA. The sub-pixels SPXn, the emission areas EMA, and the sub-areas SA of the display device 10 may be areas divided by an arrangement of the bank layer BNL. Intervals between the sub-pixels SPXn, the emission areas EMA, and the sub-areas SA may vary according to a width of the bank layer BNL.

The bank layer BNL may be disposed in a lattice-shaped pattern on a front surface of the display area DPA, including portions extending in the first and second directions DR1 and DR2 in plan view. The bank layer BNL may be disposed across boundaries between the respective sub-pixels SPXn to distinguish neighboring sub-pixels SPXn. The bank layer BNL may be disposed to surround the emission area EMA and the sub-area SA disposed in each sub-pixel SPXn to distinguish the emission area EMA and the sub-area SA.

The light emitting elements ED may be disposed in the emission area EMA. The light emitting elements ED may be disposed between the bank patterns BP1 and BP2 and be arranged to be spaced apart from each other in the first direction DR1. In an embodiment, the light emitting elements ED may have a shape extending in a direction, and have both ends each disposed on different electrodes RME. The light emitting elements ED may have a length greater than the interval between the electrodes RME spaced apart from each other in the second direction DR2. The light emitting elements ED may be arranged so that an extension direction thereof may be substantially perpendicular to the first direction DR1 in which the electrodes RME extend. However, the disclosure is not limited thereto, and the light emitting elements ED may be disposed so that the extension direction thereof may be the second direction DR2 or a direction obliquely inclined with respect to the second direction DR2.

The light emitting element groups EDG may be disposed in the emission area EMA. The light emitting element groups EDG may be disposed between the bank patterns BP1 and BP2 like the light emitting element ED. The light emitting element groups EDG may be spaced apart from the light emitting elements ED or the light emitting element groups EDG in the first direction DR1, but their arrangement may be irregular. The light emitting element groups EDG may be an abnormal light emitting element formed by clustering the light emitting elements ED or by having a light emitting element ED biased to a side. It has been illustrated in the drawings that the light emitting element group EDG may be a light emitting element group including two or more light emitting elements ED having both ends respectively disposed on different electrodes RME, and may be a light emitting element group having an end inclined to be biased to the first electrode RME1, but the disclosure is not limited thereto.

The connection electrodes CNE (CNE1 and CNE2) may be disposed on the electrodes RME and the bank patterns BP1 and BP2. The connection electrodes CNE may each have a shape extending in a direction and may be disposed to be spaced apart from each other. Each of the connection electrodes CNE may be in contact with the light emitting element ED or the light emitting element group EDG and may be electrically connected to the electrode RME or a conductive layer on a lower side thereof.

The connection electrodes CNE may include a first connection electrode CNE1 and a second connection electrode CNE2 disposed in each sub-pixel SPXn. The first connection electrode CNE1 may have a shape extending in the first direction DR1 and may be disposed on the first electrode RME1 or the first bank pattern BP1. The first connection electrode CNE1 may partially overlap the first electrode RME1 and may be disposed from the emission area EMA to the sub-area SA beyond the bank layer BNL. The second connection electrode CNE2 may have a shape extending in the first direction DR1 and may be disposed on the second electrode RME2 or the second bank pattern BP2. The second connection electrode CNE2 may partially overlap the second electrode RME2 and may be disposed from the emission area EMA to the sub-area SA beyond the bank layer BNL.

Referring to FIG. 3, in the sub-pixel SPXn including the light emitting element group EDG, the connection electrodes CNE adjacent to the light emitting element group EDG may vary depending on the shape or position of the light emitting element group EDG. As a portion of the connection electrodes CNE disposed on a top surface of the light emitting element group EDG may be etched and a portion of the connection electrodes CNE disposed on the side surface of the light emitting element group EDG may be left, the shape of the connection electrode CNE may vary.

For example, in case that the light emitting element group EDG is a first light emitting element group formed by clustering the light emitting elements ED, the opposite side surfaces of the connection electrodes CNE1 and CNE2 may be formed to be partially concave. Unlike the drawing, the opposite side surfaces of the connection electrodes CNE1 and CNE2 may have irregular concavo-convex structures to match the side surfaces of the light emitting element group EDG. As another example, in case that the light emitting element group EDG is a second light emitting element group in which a light emitting element ED is inclined to be biased to the first electrode RME1, the side surface of the first connection electrode CNE1 may be formed to be partially concave, and the second connection electrode CNE2 may be formed in parallel in the first direction DR1 that may be an extension direction.

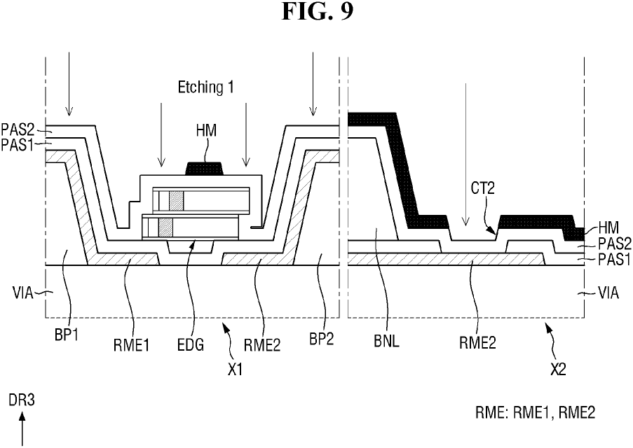

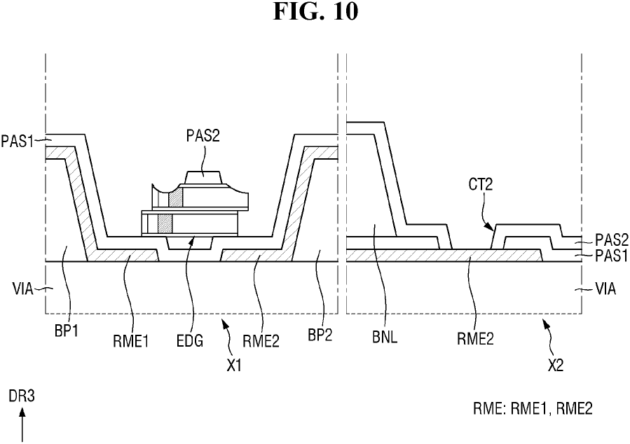

In an embodiment, in case that the connection electrodes CNE1 and CNE2 are disposed on the top surface of the light emitting element group EDG, the light emitting element group EDG may be electrically shorted, and a dark spot may be generated in the display device 10. On the same plane, a height of the light emitting element group EDG may be higher than a height (i.e., a diameter) of the light emitting element ED. Accordingly, in an etching process for forming insulating layers (e.g., a second insulating layer PAS2) among processes of manufacturing the display device 10, a portion of the surfaces of the light emitting element groups EDG may be etched and exposed (see FIGS. 9 and 10). In case that the connection electrodes CNE1 and CNE2 are disposed on the exposed surface of the light emitting element group EDG, the sub-pixel SPXn including the light emitting element group EDG may be electrically shorted, and a current may not substantially flow therethrough. Since the normal light emitting element also may not emit light due to the abnormal light emitting element disposed in the sub-pixel SPXn, lighting failure may occur in the display device 10.

The display device 10 according to an embodiment may prevent a short problem caused by the light emitting element group EDG by protecting the connection electrodes CNE1 and CNE2 connected to the light emitting element ED and removing only the connection electrodes CNE1 and CNE2 disposed on the exposed surface of the light emitting element group EDG. The display device 10 may include an organic layer 110 to protect the connection electrodes CNE1 and CNE2 connected to the light emitting element ED, and selectively remove the connection electrodes CNE1 and CNE2 connected to the light emitting element group EDG. For example, even in case that the abnormal light emitting element is present, the lighting failure of the sub-pixel SPXn may be solved by selectively removing the connection electrodes CNE1 and CNE2. This will be described in detail with reference to the drawings to be described later.

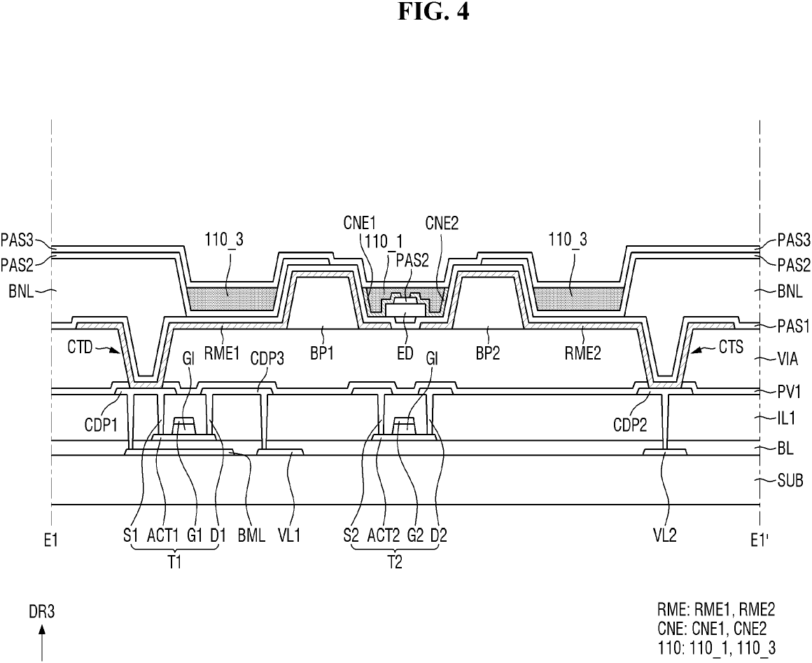

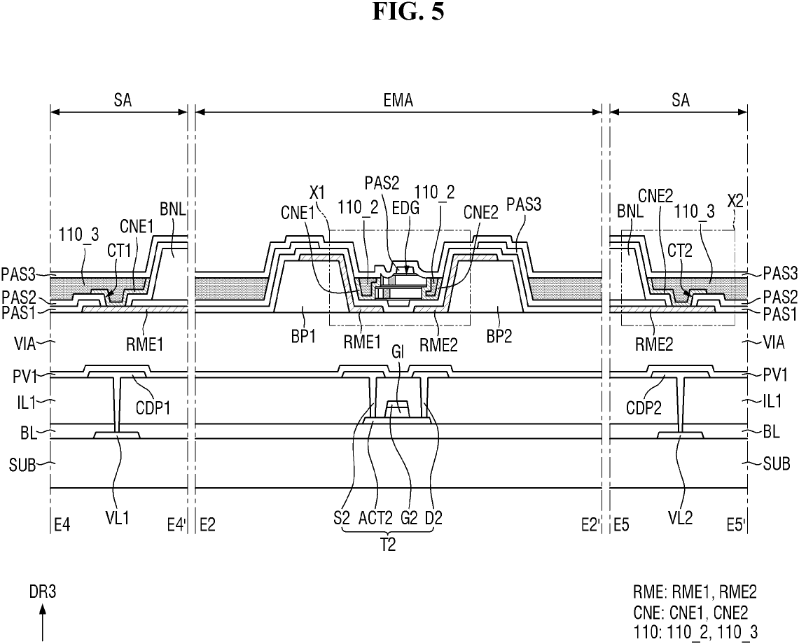

FIG. 4 is a schematic cross-sectional view taken along line E1-E1′ of FIG. 2. FIG. 5 is a schematic cross-sectional view taken along lines E2-E2′, E4-E4′, and E5-E5′ of FIG. 3.

FIG. 4 illustrates a cross section crossing both ends of the light emitting element ED and electrode contact holes CTD and CTS disposed in the first sub-pixel SPX1, and FIG. 5 illustrates a cross section crossing both ends of the first light emitting element group of the light emitting element groups EDG and contact portions CT1 and CT2 disposed in an sub-pixel SPXn.

Referring to FIGS. 4 and 5, the display device 10 may include a substrate SUB, and a semiconductor layer, conductive layers, and insulating layers disposed on the substrate SUB. The display device 10 may include electrodes RME(RME1 and RME2), a light emitting element ED, a light emitting element group EDG, and connection electrodes CNE(CNE1 and CNE2). Each of the semiconductor layer, the conductive layers, and the insulating layers may constitute a circuit layer of the display device 10.

The substrate SUB may be an insulating substrate. The substrate SUB may be made of an insulating material such as glass, quartz, or a polymer resin. The substrate SUB may be a rigid substrate, but may also be a flexible substrate capable of being bent, folded, or rolled. The substrate SUB may include a display area DPA and a non-display area NDA surrounding the display area DPA, and the display area DPA may include an emission area EMA and a sub-area SA which may be a portion of a non-emission area.

A first conductive layer may be disposed on the substrate SUB. The first conductive layer may include a lower metal layer BML, a first voltage line VL1, and a second voltage line VL2. The lower metal layer BML may be disposed to overlap an active layer ACT1 of a first transistor T1. The lower metal layer BML may perform a function of preventing light from being incident on the first active layer ACT1 of the first transistor or stabilizing electrical characteristics of the first transistor T1 by being electrically connected to the first active layer ACT1. However, the lower metal layer BML may be omitted.

A high potential voltage (or a first power voltage) transferred to the first electrode RME1 may be applied to the first voltage line VL1, and a low potential voltage (or a second power voltage) transferred to the second electrode RME2 may be applied to the second voltage line VL2. The first voltage line VL1 may be electrically connected to the first transistor T1 through a conductive pattern (e.g., a third conductive pattern CDP3) of a third conductive layer. The second voltage line VL2 may be electrically connected to the second electrode RME2 through a conductive pattern (e.g., a second conductive pattern CDP2) of a third conductive layer.

It has been illustrated in the drawing that the first voltage line VL1 and the second voltage line VL2 may be disposed on the first conductive layer, but the disclosure is not limited thereto. In some embodiments, the first voltage line VL1 and the second voltage line VL2 may be disposed on the third conductive layer and may also be directly electrically connected to the first transistor T1 and the second electrode RME2, respectively.

A buffer layer BL may be disposed on the first conductive layer and the substrate SUB. The buffer layer BL may be formed on the substrate SUB in order to protect transistors of the pixel PX from moisture permeating through the substrate SUB vulnerable to moisture permeation, and may perform a surface planarization function.

The semiconductor layer may be disposed on the buffer layer BL. The semiconductor layer may include the first active layer ACT1 of the first transistor T1 and a second active layer ACT2 of a second transistor T2. The first active layer ACT1 and the second active layer ACT2 may be respectively disposed to partially overlap a first gate electrode G1 and a second gate electrode G2 of a second conductive layer, which will be described later.

The semiconductor layer may include polycrystalline silicon, single crystal silicon, an oxide semiconductor, or the like, or a combination thereof. In another embodiment, the semiconductor layer may also include polycrystalline silicon. The oxide semiconductor may be an oxide semiconductor containing indium (In). For example, the oxide semiconductor may be at least one of indium tin oxide (ITO), indium zinc oxide (IZO), indium gallium oxide (IGO), indium zinc tin oxide (IZTO), indium gallium tin oxide (IGTO), indium gallium zinc oxide (IGZO), and indium gallium zinc tin oxide (IGZTO).

It has been illustrated in the drawing that a first transistor T1 is disposed in the sub-pixel SPXn of the display device 10, but the disclosure is not limited thereto and the display device 10 may include a larger number of transistors.

A first gate insulating layer GI may be disposed on the semiconductor layer in the display area DPA. The first gate insulating layer GI may serve as a gate insulating layer of each of the transistors T1 and T2. It has been illustrated in the drawing that the first gate insulating layer GI may be patterned together with gate electrodes G1 and G2 of a second conductive layer to be described later, and may be partially disposed between the second conductive layer and the active layers ACT1 and ACT2 of the semiconductor layer, but the disclosure is not limited thereto. In some embodiments, the first gate insulating layer GI may be entirely disposed on the buffer layer BL.

A second conductive layer may be disposed on the first gate insulating layer GI. The second conductive layer may include the first gate electrode G1 of the first transistor T1 and the second gate electrode G2 of the second transistor T2. The first gate electrode G1 may be disposed to overlap a channel area of the first active layer ACT1 in the third direction DR3, which may be the thickness direction, and the second gate electrode G2 may be disposed to overlap a channel area of the second active layer ACT2 in the third direction DR3, which may be the thickness direction. Although not illustrated in the drawings, the second conductive layer may further include an electrode of a storage capacitor.

A first interlayer insulating layer IL1 may be disposed on the second conductive layer. The first interlayer insulating layer IL1 may function as an insulating layer between the second conductive layer and other layers disposed thereon, and protect the second conductive layer.

A third conductive layer may be disposed on the first interlayer insulating layer IL1. The third conductive layer may include conductive patterns CDP1, CDP2, and CDP3, and source electrodes S1 and S2 and drain electrodes D1 and D2 of each of the transistors T1 and T2. Some of the conductive patterns CDP1, CDP2, and CDP3 may electrically connect the conductive layers or the semiconductor layers on different layers to each other and serve as the source/drain electrodes of the transistors T1 and T2.

A first conductive pattern CDP1 may be in contact with the first active layer ACT1 of the first transistor T1 through a contact hole penetrating through the first interlayer insulating layer IL1. The first conductive pattern CDP1 may be in contact with the lower metal layer BML through a contact hole penetrating through the first interlayer insulating layer IL1 and the buffer layer BL. The first conductive pattern CDP1 may serve as a first source electrode S1 of the first transistor T1. The first conductive pattern CDP1 may be electrically connected to the first electrode RME1 or the first connection electrode CNE1. The first transistor T1 may transfer the first power voltage applied from the first voltage line VL1 to the first electrode RME1 or the first connection electrode CNE1.

A second conductive pattern CDP2 may be in contact with the second voltage line VL2 through the contact hole penetrating through the first interlayer insulating layer IL1 and the buffer layer BL. The second conductive pattern CDP2 may be electrically connected to the first electrode RME1 or the first connection electrode CNE1. The second voltage line VL2 may transfer the second power voltage to the second electrode RME2 or the second connection electrode CNE2.

A third conductive pattern CDP3 may be in contact with the first voltage line VL1 through the contact hole penetrating through the first interlayer insulating layer IL1 and the buffer layer BL. The third conductive pattern CDP3 may be in contact with the first active layer ACT1 of the first transistor T1 through a contact hole penetrating through the first interlayer insulating layer IL1. The third conductive pattern CDP3 may electrically connect the first voltage line VL1 to the first transistor T1 and may serve as a first drain electrode D1 of the first transistor T1.

A second source electrode S2 and a second drain electrode D2 may be in contact with the second active layer ACT2 of the second transistor T2 through contact holes penetrating through the first interlayer insulating layer IL1, respectively. The second transistor T2 may transfer a data signal to the first transistor T1 or may transfer an initialization signal.

A first passivation layer PV1 may be disposed on the third conductive layer. The first passivation layer PV1 may function as an insulating layer between the third conductive layer and other layers and protect the third conductive layer.

The buffer layer BL, the first gate insulating layer GI, the first interlayer insulating layer IL1, and the first passivation layer PV1 described above may be formed of inorganic layers that may be alternately stacked. For example, the buffer layer BL, the first gate insulating layer GI, the first interlayer insulating layer IL1, and the first passivation layer PV1 may be formed as a double layer in which an inorganic layer including at least one of silicon oxide (SiOₓ), silicon nitride (SiNₓ), and silicon oxynitride (SiOₓN_{y}) may be stacked or multiple layers in which these layers may be alternately stacked. However, the disclosure is not limited thereto, and the buffer layer BL, the first gate insulating layer GI, the first interlayer insulating layer IL1, and the first passivation layer PV1 may also be formed of one inorganic layer including the above-described insulating material. In some embodiments, the first interlayer insulating layer IL1 may also be formed of an organic insulating material such as polyimide (PI).

A via layer VIA may be disposed on the third conductive layer in the display area DPA. The via layer VIA may include an organic insulating material, for example, an organic insulating material such as polyimide (PI) to compensate for a step caused by lower conductive layers and have a flat top surface. However, in some embodiments, the via layer VIA may be omitted.

The display device 10 may include, as a display element layer disposed on the via layer VIA, bank patterns BP1 and BP2, electrodes RME (RME1 and RME2), a bank layer BNL, light emitting elements ED, and connection electrodes CNE (CNE1 and CNE2). display device 10 may include insulating layers PAS 1, PAS2, and PAS3 disposed on the via layer VIA.

Bank patterns BP1 and BP2 may be disposed on the via layer VIA. For example, the bank patterns BP1 and BP2 may be directly disposed on the via layer VIA, and may have a structure in which at least a portion thereof protrudes from a top surface of the via layer VIA. The protruding portions of the bank patterns BP1 and BP2 may be inclined or have curved sides having a curvature, and light emitted from the light emitting element ED may be reflected by the electrodes RME disposed on the bank patterns BP1 and BP2 and then emitted in an upward direction of the via layer VIA. Unlike illustrated in the drawings, the bank patterns BP1 and BP2 may also have a curved shape with an outer surface having a curvature, for example, a semi-circular or semi-elliptical shape in cross-sectional view. The bank patterns BP1 and BP2 may include an organic insulating material such as polyimide (PI), but are not limited thereto.

The electrodes RME (RME1 and RME2) may be disposed on the bank patterns BP1 and BP2 and the via layer VIA. For example, the first electrode RME1 and the second electrode RME2 may be disposed on at least inclined side surfaces of the bank patterns BP1 and BP2. A width of the electrodes RME measured in the second direction DR2 may be smaller than a width of the bank patterns BP1 and BP2 measured in the second direction DR2, and an interval between the first electrode RME1 and the second electrode RME2 spaced apart from each other in the second direction DR2 may be smaller than an interval between the bank patterns BP1 and BP2. At least partial areas of the first electrode RME1 and the second electrode RME2 may be directly disposed on the via layer VIA, such that the first electrode RME1 and the second electrode RME2 may be disposed on the same plane.

The light emitting element ED disposed between the bank patterns BP1 and BP2 may emit light in both end directions, and the emitted light may be directed to the electrodes RME disposed on the bank patterns BP1 and BP2. The respective electrodes RME may have a structure in which portions thereof disposed on the bank patterns BP1 and BP2 may reflect the light emitted from the light emitting element ED. The first electrode RME1 and the second electrode RME2 may be disposed to cover at least one side surfaces of the bank patterns BP1 and BP2 to reflect the light emitted from the light emitting element ED.

The respective electrodes RME may be in direct contact with the third conductive layer through the electrode contact holes CTD and CTS at portions thereof overlapping the bank layer BNL between the emission area EMA and the sub-area SA. A first electrode contact hole CTD may be formed in an area where the bank layer BNL and the first electrode RME1 overlap, and a second electrode contact hole CTS may be formed in an area where the bank layer BNL and the second electrode RME2 overlap. The first electrode RME1 may be in contact with the first conductive pattern CDP1 through the first electrode contact hole CTD penetrating through the via layer VIA and the first passivation layer PV1. The second electrode RME2 may be in contact with the second voltage line VL2 through the second electrode contact hole CTS penetrating through the via layer VIA and the first passivation layer PV1. The first electrode RME1 may be electrically connected to the first transistor T1 through the first conductive pattern CDP1 to receive the first power voltage applied thereto, and the second electrode RME2 may be electrically connected to the second voltage line VL2 to receive the second power voltage applied thereto. However, the disclosure is not limited thereto. In another embodiment, the respective electrodes RME1 and RME2 may not be electrically connected to the voltage lines VL1 and VL2 of the third conductive layer, and a connection electrode CNE to be described later may be directly connected to the third conductive layer.

The electrodes RME may include a conductive material having high reflectivity. For example, the electrodes RME may include a metal such as silver (Ag), copper (Cu), aluminum (Al), or the like. In some embodiments, the electrodes RME may have a single layer comprising an alloy including aluminum (Al), nickel (Ni), lanthanum (La), or the like. In some embodiments, the electrodes RME may have a structure in which an alloy including aluminum (Al), nickel (Ni), lanthanum (La), or the like and a metal layer such as titanium (Ti), molybdenum (Mo), and niobium (Nb) may be stacked. In some embodiments, the electrodes RME may be formed of a double or multiple layers in which an alloy including aluminum (Al) and one or more metal layers made of titanium (Ti), molybdenum (Mo), and niobium (Nb) may be stacked.

The disclosure is not limited thereto, and each of the electrodes RME may further include a transparent conductive material. For example, each electrode RME may include a material such as ITO, IZO, or ITZO. In some embodiments, each of the electrodes RME may have a structure in which a transparent conductive material and a metal layer having high reflectivity may be stacked in one or more layers, or may be formed as one layer including the transparent conductive material and the metal layer having the high reflectivity. For example, each electrode RME may have a stacked structure such as ITO/Ag/ITO, ITO/Ag/IZO, or ITO/Ag/ITZO/IZO. The electrodes RME may be electrically connected to the light emitting elements ED, and may reflect some of the light emitted from the light emitting elements ED in an upward direction of the substrate SUB.

A first insulating layer PAS1 may be disposed on an entire surface of the display area DPA, and may be disposed on the via layer VIA and the electrodes RME. The first insulating layer PAS1 may include an insulating material to protect the electrodes RME and simultaneously insulate the different electrodes RME from each other. The first insulating layer PAS1 may be disposed to cover the electrodes RME before the bank layer BNL may be formed, and may thus prevent the electrodes RME from being damaged in a process of forming the bank layer BNL. The first insulating layer PAS1 may prevent the light emitting element ED disposed thereon from being damaged by being in direct contact with other members.

In an embodiment, the first insulating layer PAS1 may have a step formed so that a portion of a top surface thereof may be recessed between the electrodes RME spaced apart from each other in the second direction DR2. The light emitting element ED may be disposed on the top surface of the first insulating layer PAS1 in which the step may be formed, and a space may be formed between the light emitting element ED and the first insulating layer PAS 1.

The first insulating layer PAS1 may include contact portions CT1 and CT2 disposed in the sub-area SA. The contact portions CT1 and CT2 may be disposed to overlap different electrodes RME, respectively. For example, the contact portions CT1 and CT2 may include first contact portions CT1 disposed to overlap the first electrode RME1, and second contact portions CT2 disposed to overlap the second electrode RME2. The first contact portions CT1 and the second contact portions CT2 may penetrate through the first insulating layer PAS1 to expose a portion of a top surface of the first electrode RME1 or the second electrode RME2 on a lower side thereof. Each of the first contact portion CT1 and the second contact portion CT2 may further penetrate through some of other insulating layers disposed on the first insulating layer PAS1. The electrode RME exposed by each of the contact portions CT1 and CT2 may be in contact with the connection electrode CNE.

The bank layer BNL may be disposed on the first insulating layer PAS1. The bank layer BNL may include portions extending in the first direction DR1 and the second direction DR2, and surround each of the sub-pixels SPXn. The bank layer BNL may surround the emission area EMA and the sub-area SA of each sub-pixel SPXn to distinguish the emission area EMA and the sub-area SA of each sub-pixel SPXn, and may surround the outermost portion of the display area DPA and may distinguish the display area DPA and the non-display area NDA from each other.

The bank layer BNL may have a height, similarly to the bank patterns BP1 and BP2. In some embodiments, a height of a top surface of the bank layer BNL may be greater than that of the bank patterns BP1 and BP2, and a thickness thereof may be equal to or greater than that of the bank patterns BP1 and BP2. The bank layer BNL may prevent ink from overflowing into an adjacent sub-pixel SPXn in an inkjet printing process of the processes of manufacturing the display device 10. The bank layer BNL may include an organic insulating material such as polyimide like the bank patterns BP1 and BP2.

Referring to FIG. 4, the light emitting elements ED may be disposed on the first insulating layer PAS1 between the bank patterns BP1 and BP2. The light emitting element ED may be disposed so that an extended direction thereof may be parallel to the top surface of the substrate SUB. As will be described later, the light emitting element ED may include semiconductor layers disposed along the extended direction, and the semiconductor layers may be sequentially disposed along a direction parallel to the top surface of the substrate SUB.

The light emitting elements ED disposed in each sub-pixel SPXn may emit light of different wavelength bands according to materials of the above-described semiconductor layers. However, the disclosure is not limited thereto, and the light emitting elements ED disposed in each sub-pixel SPXn may include semiconductor layers made of the same material to emit light of the same color.

The light emitting elements ED may be in contact with the connection electrodes CNE to be electrically connected to the conductive layers on the lower side of the electrodes RME and the via layer VIA, and may receive electrical signals applied thereto to emit light of a specific wavelength band.

Referring to FIG. 5, light emitting element groups EDG may be disposed on the first insulating layer PAS1 between the bank patterns BP1 and BP2. Like the light emitting element ED, the light emitting element group EDG may be disposed so that an extended direction thereof may be parallel to the top surface of the substrate SUB. In an embodiment, the light emitting element group EDG may have a form in which two light emitting elements ED including a lower light emitting element disposed on the first insulating layer PAS1 and an upper light emitting element disposed thereon may be clustered. Each of the light emitting elements ED included in the light emitting element group EDG may include semiconductor layers disposed along the extended direction, and the semiconductor layers may be sequentially disposed along a direction parallel to the top surface of the substrate SUB.

The light emitting element groups EDG may be concavely formed by removing at least a portion of a top surface thereof. A portion of a top surface of the upper light emitting element among the light emitting elements ED of the light emitting element group EDG may be concavely formed. Since a width of the light emitting element group EDG may be approximately twice a width of the light emitting element ED, a height of the light emitting element group EDG may be approximately twice as high as a height of the light emitting element ED on a flat surface of the electrodes RME1 and RME2. Since the conditions or environment of the etching process for forming the insulating layers of the processes of manufacturing the display device 10 may be determined based on the height of the light emitting element ED, a portion of the top surface of the light emitting element group EDG may be removed together in the etching process.

Both ends of the light emitting element groups EDG may be in contact with the connection electrodes CNE1 and CNE2, but exposed top surfaces of the light emitting element groups EDG may not be in contact with the connection electrodes CNE1 and CNE2. In the case in which the connection electrodes CNE1 and CNE2 are disposed on the exposed surface of the light emitting element group EDG, since the semiconductor layers and the light emitting layer of the light emitting element group EDG are electrically connected, the light emitting element group EDG may be shorted. In an embodiment, by not disposing the connection electrodes CNE1 and CNE2 on the exposed top surface of the light emitting element group EDG, the short of the pixel PX including the light emitting element group EDG may be prevented and the dark spot of the display device 10 may be removed.

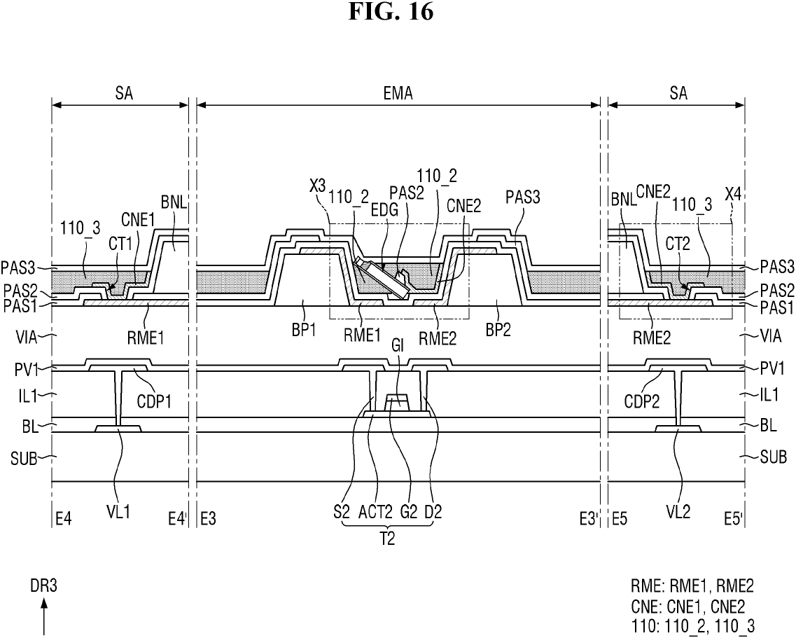

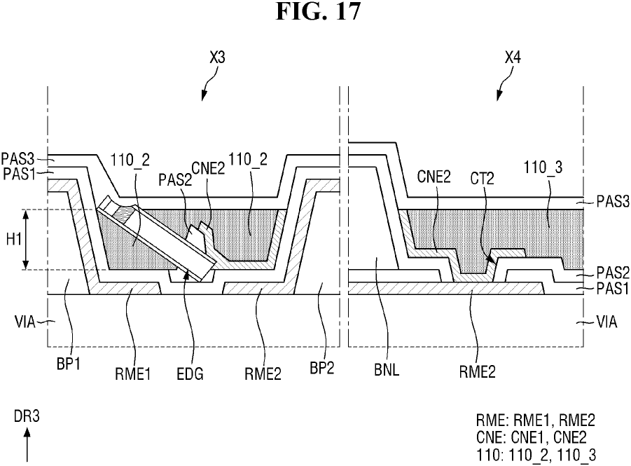

Since both ends of the light emitting element group EDG may be in contact with the connection electrodes CNE1 and CNE2, the light emitting element group EDG, like the light emitting element ED, may be electrically connected to the conductive layers on a lower side thereof, and may receive electrical signals applied thereto to emit light of a specific wavelength band. However, the disclosure is not limited thereto, and the light emitting element group EDG may be a dummy light emitting element that prevents a short but may not emit light, which will be described in detail with reference to FIGS. 16 and 17.

A second insulating layer PAS2 may be disposed on the light emitting elements ED, the light emitting element groups EDG, the first insulating layer PAS 1, and the bank layer BNL. The second insulating layer PAS2 may include a pattern portion extending in the first direction DR1 between the bank patterns BP1 and BP2 and disposed on the light emitting elements ED. The pattern portion may be disposed to partially surround outer surfaces of the light emitting element ED and the light emitting element group EDG, and may not cover both sides or both ends of the light emitting element ED and the light emitting element group EDG. The pattern portion may form a linear or island-shaped pattern in each sub-pixel SPXn in plan view. The pattern portion of the second insulating layer PAS2 may protect the light emitting element ED, and fix the light emitting elements ED in the process of manufacturing the display device 10. The pattern portion of the second insulating layer PAS2 may fix the light emitting element group EDG, but a portion of the top surfaces of the light emitting element groups EDG may be exposed in the process of forming the pattern portion. The second insulating layer PAS2 may also be disposed to fill a space between the light emitting element ED and the first insulating layer PAS1 on the lower side thereof. A portion of the second insulating layer PAS2 may be disposed on the bank layer BNL and in the sub-areas SA.

The second insulating layer PAS2 may include contact portions CT1 and CT2 disposed in the sub-area SA. The second insulating layer PAS2 may include a first contact portion CT1 disposed to overlap the first electrode RME1, and a second contact portion CT2 disposed to overlap the second electrode RME2. The contact portions CT1 and CT2 may penetrate through the second insulating layer PAS2 in addition to the first insulating layer PAS 1. Each of the first contact portions CT1 and second contact portions CT2 may expose a portion of a top surface of the first electrode RME1 or the second electrode RME2 on a lower side thereof.

The connection electrodes CNE (CNE1 and CNE2) may be disposed on the electrodes RME and the bank patterns BP1 and BP2. The first connection electrode CNE1 may be disposed on the first electrode RME1 and the first bank pattern BP1. The first connection electrode CNE1 may partially overlap the first electrode RME1 and may be disposed in the emission area EMA or may be disposed in the sub-area SA. The second connection electrode CNE2 may be disposed on the second electrode RME2 and the second bank pattern BP2. The second connection electrode CNE2 may partially overlap the second electrode RME2 and may be disposed in the emission area EMA or may be disposed in the sub-area SA.

Referring to FIG. 4, the first connection electrode CNE1 and the second connection electrode CNE2 may be respectively disposed on the second insulating layer PAS2 and may be in contact with the light emitting elements ED. The first connection electrode CNE1 may partially overlap the first electrode RME1 and may be in contact with an end of the light emitting elements ED. The second connection electrode CNE2 may partially overlap the second electrode RME2 and may be in contact with other ends of the light emitting elements ED. The connection electrodes CNE may be disposed across the emission area EMA and the sub-area SA. The connection electrodes CNE may be in contact with the light emitting elements ED at portions thereof disposed in the emission area EMA, and be electrically connected to the third conductive layer at portions thereof disposed in the sub-area SA. The first connection electrode CNE1 may be in contact with first ends of the light emitting elements ED, and the second connection electrode CNE2 may be in contact with second ends of the light emitting elements ED.

Referring to FIG. 5, in an embodiment, the first connection electrode CNE1 and the second connection electrode CNE2 may be in contact with the light emitting element groups EDG but not be in contact with the second insulating layer PAS2. The first connection electrode CNE1 may be in contact with an end of the light emitting element group EDG, and the second connection electrode CNE2 may be in contact with another end of the light emitting element group EDG and may be electrically connected to the third conductive layer in a portion thereof disposed in the sub-area SA. The first connection electrode CNE1 may be in contact with a first end of the light emitting element group EDG, and the second connection electrode CNE2 may be in contact with a second end of the light emitting element group EDG, but the disclosure is not limited thereto.

Unlike that the connection electrodes CNE1 and CNE2 may be disposed on the top surface of the light emitting element ED, the connection electrodes CNE1 and CNE2 may not be disposed on the top surface of the light emitting element group EDG. Since the connection electrodes CNE1 and CNE2 may not be disposed on the exposed top surface of the light emitting element group EDG, an electrical short of the pixel PX including the light emitting element group EDG may be prevented. The selective removal of the connection electrodes CNE1 and CNE2 may be performed by the organic layer 110 disposed to cover the connection electrodes CNE1 and CNE2. Accordingly, the connection electrodes CNE1 and CNE2 may be disposed at a position lower than the top surface of the bank patterns BP1 and BP2, for example, at a portion of the side surface thereof. A maximum height of the connection electrodes CNE1 and CNE2 may be substantially equal to a height of the organic layer 110, and top surfaces thereof may be flat to each other.

In an embodiment, each of the connection electrodes CNE may be in contact with the electrodes RME through the contact portions CT1 and CT2 disposed in the sub-area SA. The first connection electrode CNE1 may be in contact with the first electrode RME1 through the first contact portion CT1 penetrating through the first insulating layer PAS1, the second insulating layer PAS2, and a third insulating layer PAS3 in the sub-area SA. The second connection electrode CNE2 may be in contact with the second electrode RME2 through the second contact portion CT2 penetrating through the first insulating layer PAS1 and the second insulating layer PAS2 in the sub-area SA. Each of the connection electrodes CNE may be electrically connected to the third conductive layer through each of the electrodes RME. The first connection electrode CNE1 may be electrically connected to the first transistor T1 to receive the first power voltage applied thereto, and the second connection electrode CNE2 may be electrically connected to the second voltage line VL2 to receive the second power voltage applied thereto. Each of the connection electrodes CNE may be in contact with the light emitting element ED in the emission area EMA to transfer the power voltages to the light emitting element ED.

However, the disclosure is not limited thereto. In some embodiments, the connection electrodes CNE may be in direct contact with the third conductive layer, and may also be electrically connected to the third conductive layer through other patterns rather than the electrodes RME.

The connection electrodes CNE may include a conductive material. For example, the connection electrodes CNE may include ITO, IZO, ITZO, aluminum (Al), or the like, or a combination thereof. As an example, the connection electrodes CNE may include a transparent conductive material, and the light emitted from the light emitting elements ED may transmit through the connection electrodes CNE and then be emitted.

The organic layer 110 (110_1, 110_2, and 110_3) may be disposed on the connection electrodes CNE1 and CNE2 and the second insulating layer PAS2. The organic layer 110 may include the organic layers 110_1 and 110_2 disposed in the emission area EMA and the organic layer 110_3 disposed in the sub-area SA. The organic layers 110_1 and 110_2 and the organic layer 110_3 may be spaced apart from each other with the bank patterns BP1 and BP2 or the bank layer BNL interposed therebetween. The organic layers 110_1 and 110_2 may include the organic layer 110_1 disposed to cover a normal light emitting element ED and the organic layer 110_2 disposed to surround the light emitting element group EDG which may be an abnormal light emitting element.

Referring to FIG. 4, the organic layer 110_1 may be disposed between the bank patterns BP1 and BP2 to cover the light emitting element ED. The organic layer 110_1 may be disposed on the light emitting element ED, the connection electrodes CNE1 and CNE2 covering the light emitting element ED, and the second insulating layer PAS2. Since the organic layer 110_1 may be formed to be thicker than the diameter of the light emitting element ED, the organic layer 110_1 may be disposed to cover all of the light emitting element ED, the connection electrodes CNE1 and CNE2, and the pattern portion of the second insulating layer PAS2. Accordingly, the organic layer 110_1 may protect the connection electrodes CNE1 and CNE2 that cover the top surface of the normal light emitting element ED in the etching process of the connection electrodes CNE1 and CNE2 for reducing the dark spot.

Referring to FIG. 5, the organic layer 110_2 may be disposed between the bank patterns BP1 and BP2 to cover the light emitting element group EDG. The organic layer 110_2 may be exposed without covering at least a portion of a side surface of the light emitting element group EDG. For example, the light emitting element group EDG may have a shape in which a portion thereof protrudes from the top surface of the organic layer 110_2.

The organic layer 110_2 may be disposed to surround the light emitting element group EDG and the connection electrodes CNE1 and CNE2 covering the light emitting element group EDG, but may not be disposed to surround the pattern portion of the second insulating layer PAS2. Since the thickness (or height) of the organic layer 110_2 may be smaller than the diameter of the light emitting element group EDG, the organic layer 110_2 may be disposed to partially surround an end and another end of the light emitting element group EDG, and may be disposed to surround the connection electrodes CNE1 and CNE2 connected thereto. Since the organic layer 110_2 may be lower than the height of the light emitting element group EDG, the organic layer 110_2 may be lower than a height of the pattern portion of the second insulating layer PAS2 disposed on the top surface of the light emitting element group EDG, and may not be disposed on the pattern portion of the second insulating layer PAS2.

The height of the top surface of the organic layer 110_2 may be substantially the same as the height of the top surface of the connection electrodes CNE1 and CNE2 connected to the light emitting element group EDG. A surface of the organic layer 110_2 and a surface of each of the connection electrodes CNE1 and CNE2 may be substantially flat. As will be described later, since the organic layer 110_2 serves as a mask in the etching process of the connection electrodes CNE1 and CNE2 for reducing the dark spot, the connection electrodes on which the organic layer 110_2 may not be disposed may be partially etched. Since the connection electrodes CNE1 and CNE2 may be etched to a height to be planarized with a surface of the organic layer 110_2, a surface of the connection electrodes CNE1 and CNE2 may be flat to each other.

Referring to FIGS. 4 and 5, the organic layer 110_3 may be disposed to cover the connection electrodes CNE1 and CNE2 and the second insulating layer PAS2 in which the contact portions CT1 and CT2 may be formed in the sub-area SA. The organic layer 110_3 may stably apply electrical signals to the connection electrodes CNE1 and CNE2 by protecting the contact portions CT1 and CT2 in the etching process of the connection electrodes CNE1 and CNE2 for reducing the dark spot.

The organic layer 110 may include an organic insulating material. For example, the organic layer 110 may each include an acrylates resin, a urethane resin, an epoxy resin, and/or a polyimides resin, but is not limited thereto. The organic layer 110 may include a light-transmissive organic material. Since the organic layer 110 may be disposed to cover the top surface of the light emitting element ED, light emitted in an upward direction of the light emitting element ED may pass through the organic layer 110. The organic layer 110 may include a transparent organic material that may not reduce a luminous efficiency of the light emitting element ED.

It has been illustrated in the drawings that the two light emitting elements ED of the light emitting element group EDG have a cross-section overlapping each other in the upper and lower directions, but the disclosure is not limited thereto. For example, the light emitting element group EDG may have three light emitting elements ED sequentially overlapped.

The third insulating layer PAS3 may be disposed on the first connection electrode CNE1, the second connection electrode CNE2, the second insulating layer PAS2, the organic layer 110, and the light emitting element group EDG. The third insulating layer PAS3 may be completely disposed on the second insulating layer PAS2 and the organic layer 110 to cover the first connection electrode CNE1 and the second connection electrode CNE2. For example, the third insulating layer PAS3 may be disposed on the organic layers 110_1, 110_2, and 110_3, and may be in contact with the exposed top surfaces of the connection electrodes CNE1 and CNE2.

The third insulating layer PAS3 may be in contact with the exposed top surface of the light emitting element group EDG. The third insulating layer PAS3 may protect the semiconductor layers and the light emitting layer on the top surface of the light emitting element group EDG on which the connection electrodes CNE1 and CNE2 may be etched from an external environment.

Although not illustrated in the drawings, another insulating layer may be further disposed on the third insulating layer PAS3. Such an insulating layer may serve to protect the members disposed on the substrate SUB from an external environment.

Each of the first insulating layer PAS1, the second insulating layer PAS2, and the third insulating layer PAS3 described above may include an inorganic insulating material or an organic insulating material. As an example, each of the first insulating layer PAS 1, the second insulating layer PAS2, and the third insulating layer PAS3 may include an inorganic insulating material, or the first insulating layer PAS1 and the third insulating layer PAS3 may include an inorganic insulating material, and the second insulating layer PAS2 may include an organic insulating material. Each or at least one of the first insulating layer PAS1, the second insulating layer PAS2, and the third insulating layer PAS3 may also be formed in a structure in which insulating layers may be alternately or repeatedly stacked. In an embodiment, in case that the first insulating layer PAS1, the second insulating layer PAS2, and the third insulating layer PAS3 include the inorganic insulating material, each of the first insulating layer PAS1, the second insulating layer PAS2, and the third insulating layer PAS3 may be made of at least one of silicon oxide (SiOₓ), silicon nitride (SiNₓ), and silicon oxynitride (SiOₓN_{y}). In case that the first insulating layer PAS1, the second insulating layer PAS2, and the third insulating layer PAS3 include the organic insulating material, each of the first insulating layer PAS 1, the second insulating layer PAS2, and the third insulating layer PAS3 may be made of an acrylates resin, a urethane resin, an epoxy resin, a polyimides resin, or the like, or a combination thereof.

According to an embodiment, even if the display device 10 has the light emitting element group EDG formed by one or more light emitting elements ED being clustered together or biased to a side, the dark spot of the display device 10 may be reduced. The display device 10 may include the organic layer 110 to selectively remove the connection electrodes CNE1 and CNE2 from the exposed top surface of the light emitting element group EDG and protect the normal light emitting elements ED. Even if the display device 10 has the abnormal light emitting elements, dark spots or lighting failures of the display device 10 may be reduced by preventing the abnormal light emitting elements from being electrically shorted.

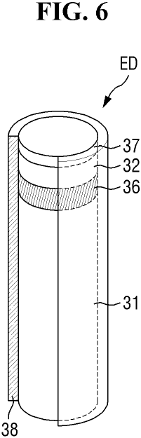

FIG. 6 is a schematic view of a light emitting element according to an embodiment.

Referring to FIG. 6, the light emitting element ED may be a light emitting diode. Specifically, the light emitting element ED may be an inorganic light emitting diode having a size of nanometers to micrometers and made of an inorganic material. The light emitting element ED may be aligned between two electrodes in which polarities may be formed in case that an electric field is formed in a specific direction between the two electrodes facing each other.

The light emitting element ED according to an embodiment may have a shape extending in a direction. The light emitting element ED may have a shape such as a cylinder, a rod, a wire, or a tube. However, the shape of the light emitting element ED is not limited thereto and the light emitting element ED may have various shapes. For example, the light emitting element ED may have a polygonal prismatic shape such as a cubic shape, a rectangular parallelepiped shape, or a hexagonal prismatic shape or have a shape extending in a direction and having an outer surface partially inclined. A diameter of the light emitting element ED may be approximately 500 to approximately 550 nm, and a length thereof may be 1 to 10 µm, in an embodiment 4 to 5 µm, but is not limited thereto.

The light emitting element ED may include a semiconductor layer doped with an arbitrary conductivity-type (e.g., p-type or n-type) dopant. The semiconductor layer may receive an electrical signal applied from an external power source to emit light of a specific wavelength band. The light emitting element ED may include a first semiconductor layer 31, a second semiconductor layer 32, a light emitting layer 36, an electrode layer 37, and an element insulating layer 38.

The first semiconductor layer 31 may be an n-type semiconductor. The first semiconductor layer 31 may include a semiconductor material having a chemical formula of AlₓGa_{y}In_{1-x-y}N (0 ≤ x ≤ 1, 0 ≤ y ≤ 1, and 0 ≤ x + y ≤ 1). For example, the semiconductor material of the first semiconductor layer 31 may be one or more of AlGaInN, GaN, AlGaN, InGaN, AlN, and InN doped with an n-type dopant. The n-type dopant doped in the first semiconductor layer 31 may be Si, Ge, Sn, Se, or the like, or a combination thereof.

The second semiconductor layer 32 may be disposed on the first semiconductor layer 31 with the light emitting layer 36 interposed therebetween. The second semiconductor layer 32 may be a p-type semiconductor, and may include a semiconductor material having a chemical formula of Al_{X}Ga_{y}In_{1-x-y}N (0 ≤ x ≤ 1, 0 ≤ y ≤ 1, and 0 ≤ x + y ≤ 1). For example, the semiconductor material of the second semiconductor layer 32 may be one or more of AlGaInN, GaN, AlGaN, InGaN, AlN, and InN doped with a p-type dopant. The p-type dopant doped in the second semiconductor layer 32 may be Mg, Zn, Ca, Ba, or the like, or a combination thereof.

It has been illustrated in the drawings that the first semiconductor layer 31 and the second semiconductor layer 32 are configured as one layer, but the disclosure is not limited thereto. The first semiconductor layer 31 and the second semiconductor layer 32 may further include a larger number of layers, for example, a clad layer or a tensile strain barrier reducing (TSBR) layer, according to a material of the light emitting layer 36. For example, the light emitting element ED may further include another semiconductor layer disposed between the first semiconductor layer 31 and the light emitting layer 36 or between the second semiconductor layer 32 and the light emitting layer 36. The semiconductor layer disposed between the first semiconductor layer 31 and the light emitting layer 36 may be any one or more of AlGaInN, GaN, AlGaN, InGaN, AlN, InN, and SLs doped with the n-type dopant, and the semiconductor layer disposed between the second semiconductor layer 32 and the light emitting layer 36 may be any one or more of AlGaInN, GaN, AlGaN, InGaN, AlN, and InN doped with the p-type dopant.

The light emitting layer 36 may be disposed between the first semiconductor layer 31 and the second semiconductor layer 32. The light emitting layer 36 may include a material having a single or multiple quantum well structure. In case that the light emitting layer 36 includes the material having the multiple quantum well structure, the light emitting layer 36 may have a structure in which quantum layers and well layers may be alternately stacked. The light emitting layer 36 may emit light by a combination of electron-hole pairs according to electrical signals applied through the first semiconductor layer 31 and the second semiconductor layer 32. The light emitting layer 36 may include a material such as AlGaN, AlGaInN, InGaN, or the like, or a combination thereof. In particular, in case that the light emitting layer 36 has the multiple quantum well structure, that is, the structure in which the quantum layers and the well layers may be alternately stacked, the quantum layers may include a material such as AlGaN or AlGaInN, and the well layers may include a material such as GaN or AlInN.

The light emitting layer 36 may also have a structure in which semiconductor materials having large band gap energy and semiconductor materials having small band gap energy may be alternately stacked, and may also include other Group III to Group V semiconductor materials according to a wavelength band of emitted light. The light emitted by the light emitting layer 36 is not limited to light of a blue wavelength band, and in some cases, the light emitting layer 36 may also emit light of red and green wavelength bands.

The electrode layer 37 may be an ohmic connection electrode. However, the disclosure is not limited thereto, and the electrode layer 37 may also be a Schottky connection electrode. The light emitting element ED may include at least one electrode layer 37. The light emitting element ED may include one or more electrode layers 37, but is not limited thereto, and the electrode layers 37 may also be omitted.

The electrode layer 37 may decrease resistance between the light emitting element ED and the electrode or the connection electrode in case that the light emitting element ED is electrically connected to the electrode or the connection electrode in the display device 10. The electrode layer 37 may include a metal having conductivity. For example, the electrode layer 37 may include at least one of aluminum (Al), titanium (Ti), indium (In), gold (Au), silver (Ag), indium tin oxide (ITO), indium zinc oxide (IZO), and indium tin zinc oxide (ITZO).

The element insulating layer 38 may be disposed to surround outer surfaces of the semiconductor layers and the electrode layer described above. For example, the element insulating layer 38 may be disposed to surround at least an outer surface of the light emitting layer 36, but may be formed to expose both ends of the light emitting element ED in a length direction. The element insulating layer 38 may also be formed so that a top surface thereof may be rounded in cross section in an area adjacent to at least an end of the light emitting element ED.

The element insulating layer 38 may include materials having insulating properties, for example, at least one of silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ). It has been illustrated in the drawings that the element insulating layer 38 may be formed as a single layer, but the disclosure is not limited thereto, and in some embodiments, the element insulating layer 38 may also be formed in a multilayer structure in which layers may be stacked.

The element insulating layer 38 may serve to protect the semiconductor layers and the electrode layer of the light emitting element ED. The element insulating layer 38 may prevent an electrical short that may occur in the light emitting layer 36 in case that the light emitting layer 36 is in direct contact with an electrode through which an electrical signal may be transferred to the light emitting element ED. The element insulating layer 38 may prevent a decrease in luminous efficiency of the light emitting element ED.

An outer surface of the element insulating layer 38 may be surface-treated. The light emitting elements ED may be sprayed onto the electrode in a state of being dispersed in an ink to be aligned. Here, in order to maintain the light emitting elements ED in a state in which the light emitting elements ED may be dispersed without being clustered with other adjacent light emitting elements ED in the ink, a hydrophobic or hydrophilic treatment may be performed on a surface of the element insulating layer 38.

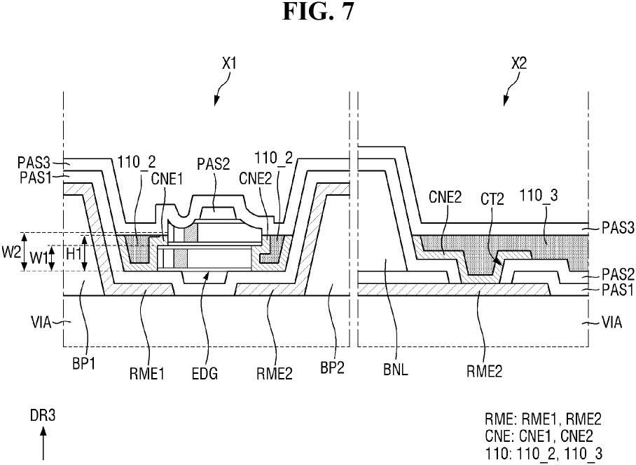

FIG. 7 is an enlarged schematic cross-sectional view of areas X1 and X2 of FIG. 5.

Referring to FIGS. 6 and 7, the light emitting element group EDG may include an upper light emitting element and a lower light emitting element, and each of the light emitting elements may include the first semiconductor layer 31, the second semiconductor layer 32, the light emitting layer 36, the electrode layer 37, and the element insulating layer 38. An end of the light emitting element group EDG on which the electrode layer 37 may be disposed may be disposed on the first electrode RME1, and another end of the light emitting element group EDG on which the first semiconductor layer 31 may be disposed may be disposed on the second electrode RME2. The light emitting element group EDG may include the semiconductor layers 31 and 32, the light emitting layer 36, and the electrode layer 37 sequentially arranged in the length direction.

The light emitting element group EDG may have a surface exposed by partially removing an outer surface thereof. For example, the top surface of the element insulating layer 38 of the light emitting element group EDG may be removed according to an etching process of the insulating layer (e.g., the second insulating layer PAS2), and the first semiconductor layer 31, the second semiconductor layer 32, the light emitting layer 36, and the electrode layer 37 may be partially exposed. The element insulating layer 38, the first semiconductor layer 31, the second semiconductor layer 32, the light emitting layer 36, and the electrode layer 37 present on the top surface of the light emitting element group EDG may be partially removed so that the light emitting element group EDG may have a concave surface.

Both ends of the light emitting element group EDG may be in contact with the connection electrodes CNE1 and CNE2, but the exposed top surface of the light emitting element group EDG may not be in contact with the connection electrodes CNE1 and CNE2. For example, in case that the light emitting layer 36 and the second semiconductor layer 32 of the light emitting element group EDG are simultaneously connected to the connection electrode as surfaces of the light emitting layer 36 and the second semiconductor layer 32 of the light emitting element group EDG are exposed, the light emitting element group EDG may be electrically shorted. The electrical short of the light emitting element group EDG may cause a dark spot in the display device 10. Accordingly, the exposed top surfaces of the semiconductor layers 31 and 32, the light emitting layer 36, and the electrode layer 37 of the light emitting element group EDG may not be in contact with the connection electrodes CNE1 and CNE2.

In an embodiment, since the light emitting element group EDG has the structure in which the two light emitting elements ED may be stacked on the first insulating layer PAS1, a width (or height) of the substrate SUB of the light emitting element group EDG in the thickness direction may be twice a diameter of the light emitting element ED. For example, the width of the light emitting element group EDG may be 1000 nm or more and 1100 nm or less, but is not limited thereto.

The second insulating layer PAS2 may include a pattern portion disposed to partially surround the outer surface of the light emitting element group EDG. The remaining portion of the outer surface of the light emitting element group EDG may be etched except for a portion thereof on which the pattern portion of the second insulating layer PAS2 may be disposed. The disclosure is not limited thereto, but in an etching process for forming the pattern portion of the second insulating layer PAS2, a portion of the element insulating layer 38 that may be the outer surface of the light emitting element group EDG may be etched.

The connection electrodes CNE1 and CNE2 may be disposed at both ends of the light emitting element group EDG. The connection electrodes CNE1 and CNE2 may not be disposed on the top surface of the light emitting element group EDG. The connection electrodes CNE1 and CNE2 may be connected to the electrodes RME1 and RME2 through the contact portions CT1 and CT2 of the second insulating layer PAS2. As an example, in case that the connection electrodes CNE1 and CNE2 are in contact with both ends of the light emitting element group EDG, the first power voltage and the second power voltage applied to the connection electrodes CNE1 and CNE2 may be transferred to the light emitting element group EDG. Accordingly, the light emitting element group EDG may emit light of a specific wavelength band according to a voltage. As another example, in case that the connection electrodes CNE1 and CNE2 are in contact with only an end of the light emitting element group EDG or are not in contact therewith, the light emitting element group EDG may not emit light.

The organic layer 110 may be disposed on the connection electrodes CNE1 and CNE2, and may be disposed to surround the light emitting element group EDG. The organic layer 110_2 disposed between the bank patterns BP1 and BP2 may be disposed to cover all of the side surfaces and a portion of the top surfaces of the connection electrodes CNE1 and CNE2.

A height H1 of the organic layer 110 may be greater than a diameter W1 of the light emitting element ED and smaller than about 1.5 times (‘W2’ in FIG. 7) the diameter of the light emitting element ED. In case that the diameter of one light emitting element ED is approximately 500 nm to approximately 550 nm, the height H1 of the organic layer 110 may be in a range of approximately 500 nm to approximately 825 nm. In the process of etching the insulating layers of the process of manufacturing the display device 10, the thickness to which the top surface of the light emitting element group EDG may be removed may not exceed half the diameter of one light emitting element ED. For example, the top surface of the light emitting element group EDG may be removed by the diameter of at most one light emitting element ED. Accordingly, even if a portion of the top surface of the light emitting element group EDG may be removed, the light emitting element group EDG may have a height of about 1.5 times or more of the diameter of the light emitting element ED.

The height H1 of the organic layer 110 may be equal to or lower than the height W2 of the exposed top surface of the light emitting element group EDG. The height H1 of the organic layer 110 may be equal to or greater than the diameter W1 of the light emitting element ED corresponding to the height of the lower light emitting element. Accordingly, the organic layer 110 may serve as a mask to remove the connection electrodes CNE1 and CNE2 disposed on the exposed top surface of the light emitting element group EDG, and protect the connection electrodes CNE1 and CNE2 disposed on the top surface of the light emitting element ED.

Top surfaces of the connection electrodes CNE1 and CNE2 and the organic layer 110 may be flat. A maximum height of the connection electrodes CNE1 and CNE2 may be substantially equal to the height H1 of the organic layer 110.

In an embodiment, the ‘height’ means a length from the same plane to the top surface of the component, and it has been illustrated in the drawings that the ‘height’ may be the length from a surface of the first insulating layer PAS1 to a top surface of each component.

Although not illustrated, in case that the light emitting element group EDG includes three or more light emitting elements ED sequentially stacked, the etching process of the insulating layers may be performed based on one light emitting element ED. Therefore, the height of the light emitting element group EDG may be about 1.5 times or more of the diameter of the light emitting element ED, and the height H1 of the organic layer 110 may be the same as described above. However, in some embodiments, the height of the light emitting element group EDG may be smaller than about 1.5 times the diameter of the light emitting element ED, and accordingly, the height H1 of the organic layer 110 may be appropriately adjusted.

The third insulating layer PAS3 may be in contact with the exposed top surface of the light emitting element group EDG, the connection electrodes CNE1 and CNE2, and the organic layer 110. The third insulating layer PAS3 may be in contact with the first semiconductor layer 31, the second semiconductor layer 32, the light emitting layer 36, and the electrode layer 37 of the light emitting element group EDG exposed by removing the connection electrodes CNE1 and CNE2. The third insulating layer PAS3 may protect the first semiconductor layer 31, the second semiconductor layer 32, the light emitting layer 36, and the electrode layer 37 of the light emitting element group EDG from external environments.

According to an embodiment, even if the display device 10 has the light emitting element group EDG formed by one or more light emitting elements ED being clustered together or biased to a side, the dark spot of the display device 10 may be reduced. The organic layer 110 of the display device 10 may selectively remove the connection electrodes CNE1 and CNE2 from the exposed top surface of the light emitting element group EDG and protect the normal light emitting elements ED. Even if the display device 10 has the abnormal light emitting elements, dark spots or lighting failures of the display device 10 may be reduced by preventing the abnormal light emitting elements from being electrically shorted.

Hereinafter, a process for manufacturing the light emitting element ED will be described with reference to other drawings.

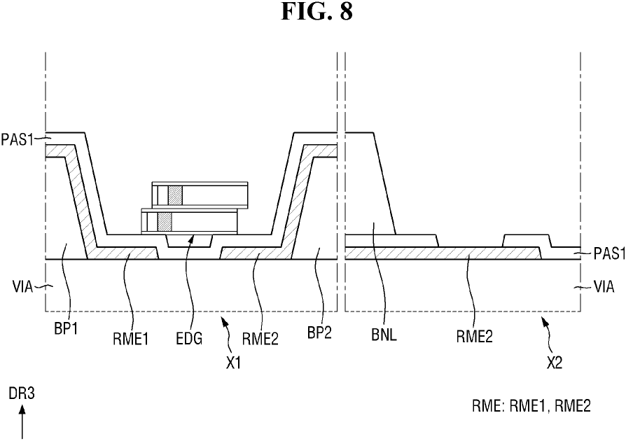

FIGS. 8 to 15 are schematic cross-sectional views illustrating a method of manufacturing a display device according to an embodiment.

Referring to FIG. 8, the light emitting elements ED may be aligned on the first electrode RME1 and the second electrode RME2 spaced apart from each other on the substrate SUB, and the light emitting element group EDG may be partially aligned.

Prior to alignment, the light emitting elements ED may be prepared by being mixed in a solution, and the solution including the light emitting elements ED may be discharged on the first insulating layer PAS1 by an inkjet printing method, but is not limited thereto.

An electric field in a specific direction may be formed between the first electrode RME1 and the second electrode RME2, and the light emitting elements ED or the light emitting element groups EDG in the solution may be aligned between the first electrode RME1 and the second electrode RME2.

The light emitting element ED may have a shape of a light emitting element group EDG having a structure in which light emitting elements ED may be clustered and vertically stacked.

Referring to FIGS. 9 and 10, an insulating material layer (‘PAS2’ in FIG. 9) may be formed on the light emitting element group EDG, and the insulating material layer PAS2 may be etched to form the second insulating layer PAS2. Accordingly, a portion of the top surface of the light emitting element group EDG may be exposed.

Referring to FIG. 9, a hard mask HM may be formed on the insulating material layer PAS2. The insulating material layer PAS2 may be etched in the third direction DR3 along the hard mask HM. A second insulating layer PAS2 may be formed.

For example, a process of etching the insulating material layer PAS2 may be a dry etching method, a wet etching method, a reactive ion etching (RIE) method, an inductively coupled plasma reactive ion etching (ICP-RIE) method, or the like. In the case of the dry etching method, anisotropic etching may be possible, and the dry etching method may thus be suitable for vertical etching. In an embodiment, the insulating material layer PAS2 may be etched in the third direction DR3 through the dry etching method.

After the insulating material layer PAS2 may be etched, a pattern portion and a second contact portion CT2 (or a first contact portion CT1) of the second insulating layer PAS2 may be formed. The pattern portion of the second insulating layer PAS2 may be disposed on the light emitting element group EDG, and the second contact portion CT2 of the second insulating layer PAS2 may expose the second electrode RME2.

Referring to FIG. 10, the surface of the light emitting element group EDG formed by etching the insulating material layer PAS2 may be exposed. Since the conditions of the etching process for forming the second insulating layer PAS2 may be determined based on the height of one light emitting element ED, a portion of the top surface of the light emitting element group EDG having a height higher than that of the second insulating layer PAS2 may be removed together in the etching process. Accordingly, the first semiconductor layer 31, the second semiconductor layer 32, the light emitting layer 36, and the electrode layer 37 corresponding to the upper light emitting elements of the light emitting element group EDG may be partially exposed. As the element insulating layer 38 present on the top surface of the light emitting element group EDG may be removed, the surfaces of the first semiconductor layer 31, the second semiconductor layer 32, the light emitting layer 36, and the electrode layer 37 may be exposed or partially removed so that the light emitting element group EDG may have a concave surface.

It has been illustrated in the drawing that the top surface of the light emitting element group EDG is exposed in the step of forming the second insulating layer PAS2, but the disclosure is not limited thereto. For example, the top surface of the light emitting element group EDG may be exposed in the same manner in the process of etching the first insulating layer PAS1 or in the process of etching other insulating layers.

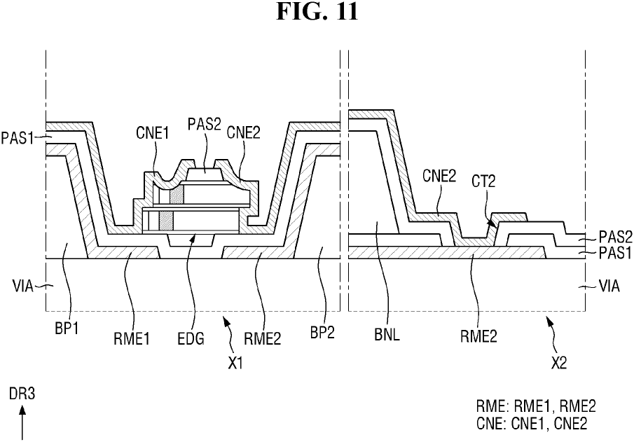

Referring to FIG. 11, connection electrodes CNE1 and CNE2 may be formed on the light emitting element group EDG.

The connection electrodes CNE1 and CNE2 may be formed on a first end, a second end, and a partially exposed top surface of the light emitting element group EDG. The connection electrodes CNE1 and CNE2 may be disposed on the first semiconductor layer 31, the second semiconductor layer 32, the light emitting layer 36, and the electrode layer 37 of the light emitting element group EDG, and may be in contact therewith. The connection electrodes CNE1 and CNE2 may be disposed on the second insulating layer PAS2, and may be in contact with the second electrode RME2 at the second contact portion CT2 of the second insulating layer PAS2. For example, the first connection electrode CNE1 may be in contact with the first end, the electrode layer 37, the second semiconductor layer 32, and the light emitting layer 36 of the light emitting element group EDG, and the second connection electrode CNE2 may be in contact with the second end and the first semiconductor layer 31 of the light emitting element group EDG.

In case that the first connection electrodes CNE1 and CNE2 are in contact with the light emitting layer 36 and the second semiconductor layer 32, the light emitting element group EDG to which the same voltage is applied may be electrically shorted. In this case, since the dark spots may occur in the display device 10, the electrical short may be prevented by removing the connection electrodes CNE1 and CNE2 according to an embodiment.

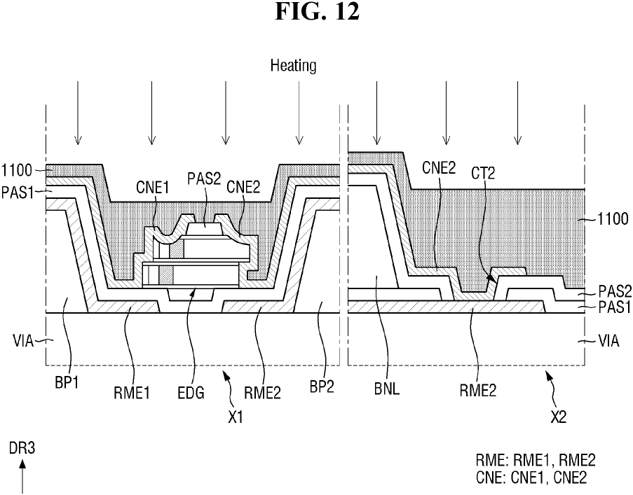

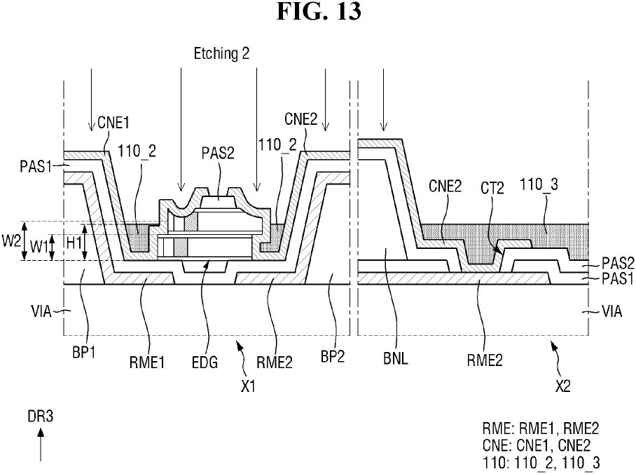

Referring to FIGS. 12 and 13, the organic layer 110 may be formed on the light emitting element group EDG, the light emitting element ED, and the connection electrodes CNE1 and CNE2.

First, in FIG. 12, an organic material layer 1100 having a height sufficiently high to cover all of the light emitting element group EDG, the light emitting element ED, and the connection electrodes CNE1 and CNE2 may be formed. The organic material layer 1100 may correspond to the organic layer 110. For example, the organic material layer 1100 may include a light-transmissive organic material in the same manner as the organic layer 110. The organic material layer 1100 may be entirely coated on the bank patterns BP1 and BP2, the bank layer BNL, and the first connection electrode CNE1 and the second connection electrode CNE2 disposed thereon.

Referring to FIG. 13, the organic layer 110 planarized by heat-treating the organic material layer 1100 may be formed. The organic material layer 1100 may be planarized by heat applied from an oven, and the organic layer 110 may have an appropriate height to expose the connection electrodes CNE1 and CNE2 disposed on the exposed top surface of the light emitting element group EDG.

The height H1 of the organic layer 110 may be equal to or greater than the diameter W1 of the light emitting element ED corresponding to the height of the lower light emitting element. For example, since the organic layer 110 may be higher than the height of the connection electrodes CNE1 and CNE2 disposed on the top surface of the light emitting element ED, the organic layer 110 may protect the connection electrodes CNE1 and CNE2 in a subsequent process of etching the connection electrodes CNE1 and CNE2.

The height H1 of the organic layer 110 may be equal to or lower than the height W2 of the exposed top surface of the light emitting element group EDG. For example, the organic layer 110 may be equal to or lower than the height of bottom surfaces of the connection electrodes CNE1 and CNE2 disposed on the exposed top surface of the light emitting element group EDG. The organic layer 110 may have a height sufficient to etch all of the connection electrodes CNE1 and CNE2 disposed on the exposed top surface of the light emitting element group EDG. For example, the organic layer 110 may not cover the connection electrodes NE1 and CNE2 disposed on the top surface of the light emitting element group EDG.

For example, the height H1 of the organic layer 110 may be greater than a diameter W1 of the light emitting element ED and smaller than about 1.5 times (‘W2’ in FIG. 13) the diameter of the light emitting element ED. In case that the diameter of one light emitting element ED is approximately 500 nm to approximately 550 nm, the height H1 of the organic layer 110 may be approximately 500 nm or more and approximately 825 nm or less.

However, the disclosure is not limited thereto, and in case that the organic layer 110 may be planarized while having a constant height H1, a process of coating and heat-treating the organic material layer 1100 may be omitted.

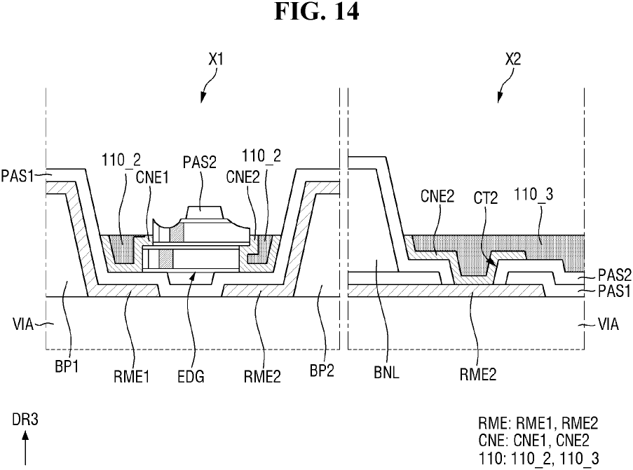

Referring to FIG. 14, portions of the connection electrodes CNE1 and CNE2 on which the organic layer 110 is not disposed may be etched. The organic layer 110 may be used as a mask layer for etching the connection electrodes CNE1 and CNE2 like a photo-resist layer. The organic layer 110 may expose an area disposed on the exposed top surface of the light emitting element group EDG. The exposed connection electrodes CNE1 and CNE2 on which the organic layer 110 is not disposed may be removed through an etching process. The etching process may be performed as a dry etching process or a wet etching process, but in an embodiment may be performed as a wet etching process.

The first connection electrode CNE1 disposed on the exposed first semiconductor layer 31 of the light emitting element group EDG, and the second connection electrode CNE2 disposed on the second semiconductor layer 32, the light emitting layer 36, and the electrode layer 37 may be removed by the etching process. Accordingly, the exposed top surfaces of the semiconductor layers 31 and 32, the light emitting layer 36, and the electrode layer 37 of the light emitting element group EDG may not be in contact with the connection electrodes CNE1 and CNE2.

Since the organic layer 110 may be disposed to cover all the connection electrodes CNE1 and CNE2 connected to the light emitting element ED and the connection electrodes CNE1 and CNE2 connected to the electrodes RME1 and RME2 through the contact portions CT1 and CT2, the connection electrodes CNE1 and CNE2 connected to the light emitting element ED may be electrically stabilized.

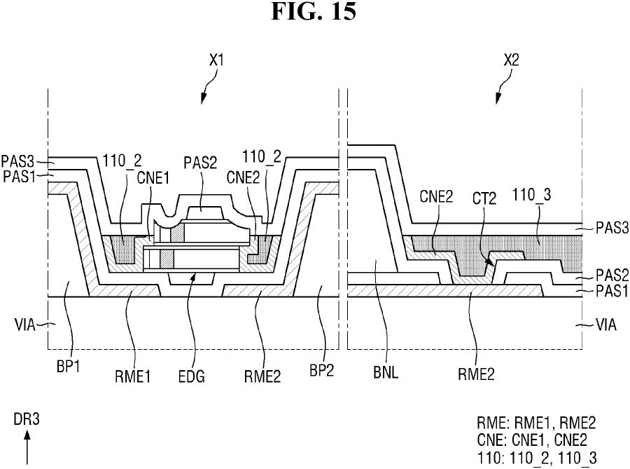

Finally, referring to FIG. 15, a third insulating layer PAS3 may be formed on the connection electrodes CNE1 and CNE2, the light emitting element group EDG, and the second insulating layer PAS2. The third insulating layer PAS3 may be disposed to protect the exposed surfaces after the connection electrodes CNE1 and CNE2 disposed on the top surface of the light emitting element group EDG may be etched. Through the third insulating layer PAS3, the exposed top surfaces of the semiconductor layers 31 and 32, the light emitting layer 36, and the electrode layer 37 of the light emitting element group EDG may be in contact with the connection electrodes CNE1 and CNE2.

Even if the display device 10 includes the light emitting element groups EDG, which may be the abnormal light emitting element, the display device 10 having reduced dark spots may be manufactured by preventing the light emitting element groups EDG from being electrically shorted through the processes described above.

FIG. 16 is a schematic cross-sectional view taken along lines E3-E3′, E4-E4′, and E5-E5′ of FIG. 3.

FIG. 16 illustrates a cross-section crossing both ends of a second light emitting element group among the light emitting element groups EDG and the contact portions CT1 and CT2 disposed in the sub-pixel SPXn.

Here, the light emitting element group EDG may have a structure in which a center point of the light emitting element ED deviates from a center between the first electrode RME1 and the second electrode RME2. The light emitting element group EDG may be disposed to be inclined on the first bank pattern BP1 to be biased to the first electrode RME1, or may be disposed to be inclined on the second bank pattern BP2 to be biased to the second electrode RME2.

According to an embodiment, the light emitting element group EDG may be fixed by the pattern portion of the second insulating layer PAS2 and may be surrounded by the organic layer 110_2, similarly to FIG. 5. The light emitting element group EDG may be in contact with only the second connection electrode CNE2 among the connection electrodes CNE1 and CNE2. For example, an end of the light emitting element group EDG may protrude from a surface of the organic layer 110_2, and as illustrated in FIGS. 13 and 14, according to the process of etching the connection electrodes CNE1 and CNE2, the first connection electrode CNE1 disposed at an end of the light emitting element group EDG may be removed together. The second connection electrode CNE2 disposed at another end of the light emitting element group EDG may not be removed.

In case that the connection electrodes CNE1 and CNE2 are in contact with only an end of the light emitting element group EDG or are not in contact therewith, the light emitting element group EDG may not emit light. For example, the light emitting element group EDG may be a dummy light emitting element that may not emit light. Even in this case, since an electrical short of the light emitting element group EDG may be prevented, it may be possible to prevent the dark spot from occurring in the display device 10 caused by the entirety of one sub-pixel SPXn of the display device 10 not emitting light.

FIG. 17 is an enlarged schematic cross-sectional view of areas X3 and X4 of FIG. 16.

The light emitting element group EDG may protrude from a surface of the organic layer 110_2. The height H1 of the organic layers 110_2 and 110_3 may be lower than or equal to the height of the exposed surface of the inclined light emitting element group EDG. According to the process of etching the insulating layer, some of the first semiconductor layer 31, the second semiconductor layer 32, the light emitting layer 36, and the electrode layer 37 corresponding to the surface of the light emitting element group EDG may be partially exposed, and the connection electrodes CNE1 and CNE2 may be disposed on the surface thereof to prevent an electrical short from occurring.

It has been illustrated in the drawing that some of the surfaces of the element insulating layer 38, the electrode layer 37, the second semiconductor layer 32, and the light emitting layer 36 of the light emitting element group EDG are removed, but the disclosure is not limited thereto (see FIG. 6).

The third insulating layer PAS3 may be disposed to protect the exposed surfaces after the connection electrodes CNE1 disposed on the top surface of the light emitting element group EDG may be etched. The third insulating layer PAS3 may be in direct contact with the surfaces of the electrode layer 37, the second semiconductor layer 32, and the light emitting layer 36 to protect the electrode layer 37, the second semiconductor layer 32, and the light emitting layer 36.

Hereinafter, another embodiment of the display device 10 according to an embodiment will be described. In the following embodiments, the same components as those of the above-described embodiments will be denoted by the same reference numerals, and an overlapping description thereof will be omitted or simplified and differences will be described.

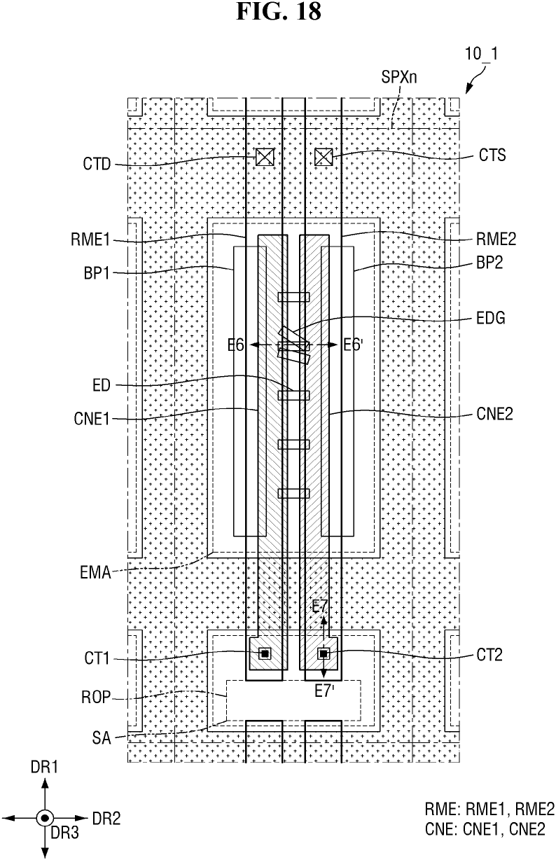

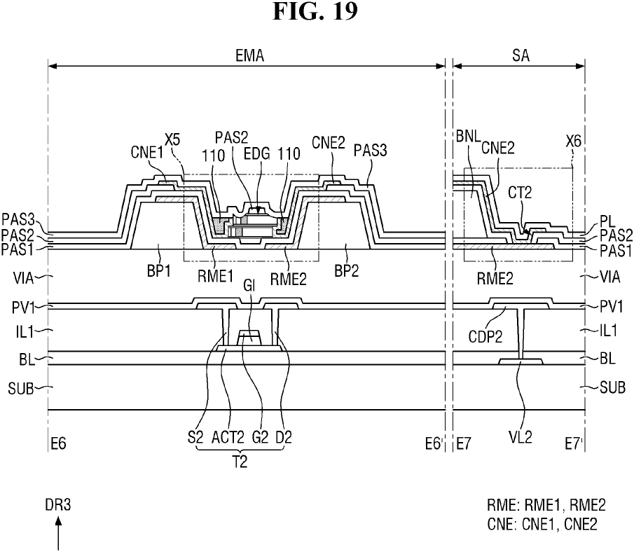

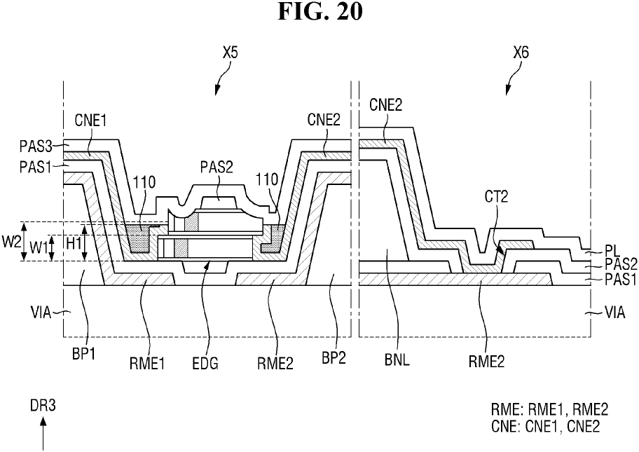

FIG. 18 is a schematic plan view illustrating a sub-pixel of a display device according to another embodiment. FIG. 19 is a schematic cross-sectional view taken along lines E6-E6′ and E7-E7′ of FIG. 18. FIG. 20 is an enlarged schematic cross-sectional view of areas X5 and X6 of FIG. 18.

In the embodiment, since the organic layer 110 may be formed at a selective position, a precision of a process of manufacturing a display device 10_1 may be increased. An embodiment may be different from a previous embodiment at least in that the connection electrodes CNE1 and CNE2 disposed on the bank patterns BP1 and BP2 may not be etched, and only the connection electrodes CNE1 and CNE2 disposed on the light emitting element group EDG may be selectively etched.

Specifically, referring to FIG. 18, since the connection electrodes CNE1 and CNE2 disposed on the side and top surfaces of the bank patterns BP1 and BP2 may not be etched, the connection electrodes CNE1 and CNE2 may have a greater width in the second direction DR2 than in a previous embodiment.

Referring to FIGS. 19 and 20, the display device 10_1 may include a passivation layer PL to protect the second contact portion CT2 connecting the second electrode RME2 and the second connection electrode CNE2. The passivation layer PL may be disposed in the sub-area SA. Since the passivation layer PL may protect the second contact portion CT2, the connection electrodes CNE1 and CNE2 disposed on the second contact portion CT2 may be protected without being etched even if the organic layer 110 may not be disposed on the second contact portion CT2 in a subsequent process. Although not illustrated, the passivation layer PL may be disposed to protect the first contact portion CT1 connecting the first electrode RME1 and the first connection electrode CNE1.

The passivation layer PL may include an inorganic insulating material or an organic insulating material. In an embodiment, in case that the passivation layer PL includes the inorganic insulating material, the inorganic insulating material may be at least one of silicon oxide (SiOₓ), silicon nitride (SiNₓ), and silicon oxynitride (SiOₓN_{y}).

The connection electrodes CNE1 and CNE2 may be disposed on both ends of the light emitting element group EDG, the bank patterns BP1 and BP2, and the bank layer BNL. An embodiment may be different from a previous embodiment in that the connection electrodes CNE1 and CNE2 may be disposed on the uppermost portions of the bank patterns BP and BP2 and the bank layer BNL.

The organic layer 110 may be disposed only in the emission area EMA. The organic layer 110 may not be disposed in the sub-area SA. The organic layer 110 may be disposed only between the bank patterns BP1 and BP2. The organic layer 110 may be disposed to surround the light emitting element group EDG, and may be disposed to expose a portion of the light emitting element group EDG. The organic layer 110 disposed between the bank patterns BP1 and BP2 may have substantially the same structure as the organic layer 110_2 of the previous embodiment and include the same organic material as the organic layer 110_2 of the previous embodiment.

The display device 10_1 according to an embodiment may include the passivation layer PL protecting the sub-area SA and the organic layer 110 disposed only between the bank patterns BP1 and BP2. Since the organic layer 110 may be selectively disposed only in a local area requiring removal of the connection electrodes CNE1 and CNE2, the precision of the manufacturing process may be increased.

Hereinafter, a process for manufacturing the light emitting element ED will be described with reference to other drawings.

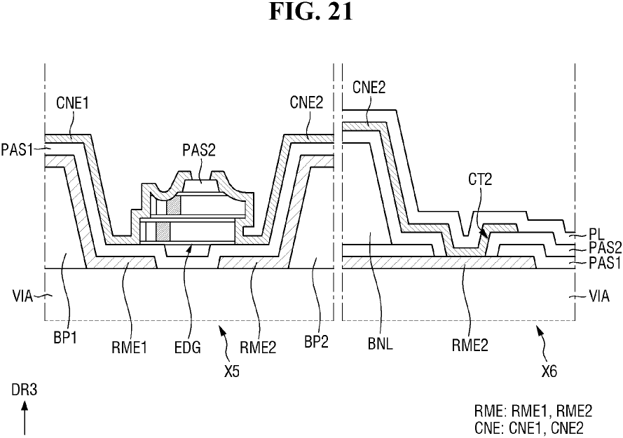

FIGS. 21 to 24 are schematic cross-sectional views illustrating a method of manufacturing a display device according to another embodiment.

Referring to FIG. 21, the light emitting element group EDG may be aligned on the first electrode RME1 and the second electrode RME2 spaced apart from each other on the substrate SUB. The second insulating layer PAS2 may be formed by forming an insulating material layer on the light emitting element group EDG and etching the insulating material layer. In the etching process, the surface of the light emitting element group EDG may be exposed. The connection electrodes CNE1 and CNE2 may be formed on the light emitting element group EDG whose upper portion may be partially exposed (see FIGS. 8 to 11).

Next, the passivation layer PL protecting the contact portions CT1 and CT2 connecting the connection electrodes CNE1 and CNE2 and the electrodes RME1 and RME2 may be formed on the connection electrodes CNE1 and CNE2.

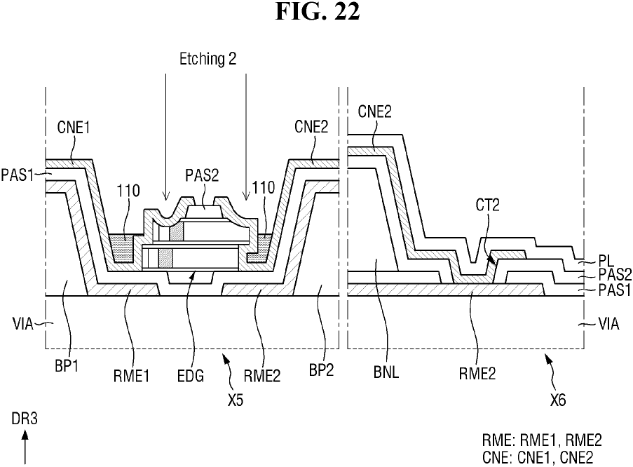

Referring to FIG. 22, the organic layer 110 may be selectively formed only between the bank patterns BP1 and BP2. The process of forming the organic layer 110 may be performed by the same process as in the previous embodiments, but is not limited thereto. The organic layer 110 may be disposed to surround the light emitting element group EDG.

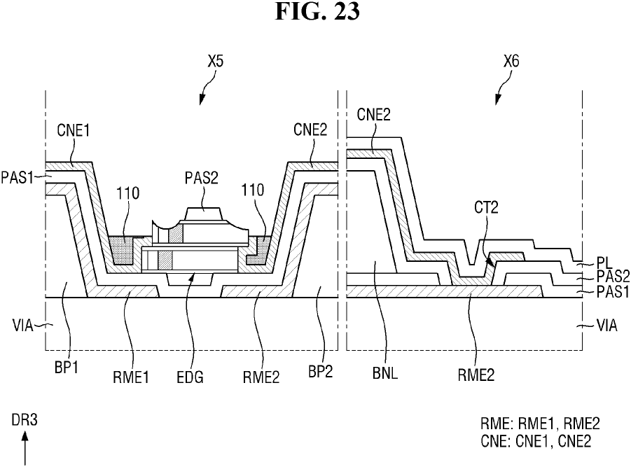

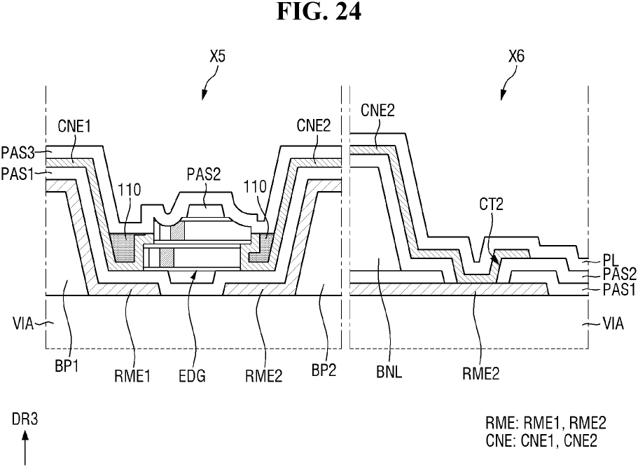

Referring to FIGS. 23 and 24, the connection electrodes CNE1 and CNE2 in the area where the organic layer 110 is not disposed may be etched. Thereafter, the third insulating layer PAS3 in contact with a surface of the light emitting element group EDG exposed by etching the connection electrodes CNE1 and CNE2 may be formed.

According to an embodiment, even if the organic layer 110 may not be disposed on the first contact portion CT1 or the second contact portion CT2, the first contact portion CT1 or the second contact portion CT2 may be protected by the passivation layer PL. Accordingly, the organic layer 110 may be selectively coated on a desired area.

According to an embodiment, in case that the organic material layer (‘1100’ in FIG. 12) is coated on the entire surface of the display device and then heat-treated to be planarized, a slope caused by the bank patterns BP1 and BP2 and the bank layer BNL may need to be considered. For example, in case that the organic material layer 1100 is coated on the bank patterns BP1 and BP2 and the bank layer BNL having different heights, reflow needs to be considered. According to an embodiment, by not coating the organic layer 110 on the bank patterns BP1 and BP2 and the bank layer BNL, there may be no need to consider the reflow of the organic layer 110, and the organic layer 110 may be selectively coated only on necessary portions. Accordingly, the precision of the process of the display device 10 may be improved, and planarization of the organic layer 110 may be improved.

In concluding the detailed description, those skilled in the art will appreciate that many variations and modifications can be made to embodiments without departing from the principles of the disclosure. Therefore, the disclosed embodiments are used in a generic and descriptive sense only and not for purposes of limitation.

What is claimed is:

1. A display device comprising:
a first electrode and a second electrode that are disposed on a substrate to be spaced apart from each other;
a first insulating layer disposed on the first electrode and the second electrode;
a light emitting element disposed on the first insulating layer;
a first connection electrode in electrical contact with a first end of the light emitting element on the first insulating layer; and
an organic layer disposed on the first connection electrode and surrounding the light emitting element.

2. The display device of claim 1, wherein a top surface of the organic layer and a top surface of the first connection electrode are flat to each other.

3. The display device of claim 1, wherein a portion of a top surface of the light emitting element protrudes from a surface of the organic layer.

4. The display device of claim 1, wherein the first connection electrode is not disposed on a top surface of the light emitting element.

5. The display device of claim 1, wherein
a height of the organic layer is greater than a diameter of the light emitting element, and
a height of the organic layer is smaller than about 1.5 times the diameter of the light emitting element.

6. The display device of claim 1, wherein a height of the organic layer is in a range of about 500 nm to about 825 nm.

7. The display device of claim 1, wherein the organic layer includes a light-transmissive organic material.

8. The display device of claim 1, wherein
the light emitting element includes:
semiconductor layers;
a light emitting layer disposed between the semiconductor layers; and
an element insulating layer partially surrounding outer side surfaces of the semiconductor layers and the light emitting layer, and
the element insulating layer exposes a surface of the light emitting layer.

9. The display device of claim 8, further comprising:
a second insulating layer disposed on the light emitting element and the organic layer,
wherein the second insulating layer is in physical contact with the light emitting layer.

10. The display device of claim 1, wherein
the first connection electrode is electrically connected to the first electrode through a contact portion, and
the organic layer is disposed to cover the contact portion.

11. The display device of claim 10, wherein
the organic layer includes a portion disposed on the contact portion and another portion surrounding the light emitting element, and
the portion and the another portion are spaced apart from each other with a bank layer interposed therebetween.

12. The display device of claim 1, wherein
the light emitting element has a second end opposite the first end,
the second end is in electrical contact with a second connection electrode disposed on the first insulating layer, and
a top surface of the second connection electrode and a top surface of the organic layer are flat to each other.

13. The display device of claim 1, further comprising:
a passivation layer disposed to cover the first connection electrode,
wherein the first connection electrode is electrically connected to the first electrode through a contact portion.

14. A method of manufacturing a display device, the method comprising:
aligning a light emitting element on a first electrode and a second electrode spaced apart from each other on a substrate;
at least partially exposing semiconductor layers of the light emitting element;
forming connection electrodes on the light emitting element;
forming an organic layer on the light emitting element and the connection electrodes; and
etching a portion of the connection electrodes on which the organic layer is not disposed.

15. The method of claim 14, wherein the forming of the organic layer includes:
forming an organic material layer covering the light emitting element and the connection electrodes; and
heat-treating and planarizing the organic material layer.

16. The method of claim 14, wherein a height of the organic layer is formed lower than a height of exposed top surfaces of the semiconductor layers.

17. The method of claim 14, wherein the at least partially exposing of the semiconductor layers of the light emitting element includes:
forming an insulating material layer on the light emitting element, and
etching the insulating material layer to form an insulating layer.

18. The method of claim 14, wherein the etching of the connection electrode is performed to etch the connection electrode disposed on the exposed semiconductor layers of the light emitting element among the connection electrodes.

19. The method of claim 14, further comprising:
forming an insulating layer on the connection electrodes and the light emitting element,
wherein the insulating layer is disposed to be in physical contact with the exposed semiconductor layers of the light emitting element.

20. The method of claim 14, further comprising:
before the forming of the organic layer, forming a passivation layer disposed to cover a contact portion connecting the connection electrodes and a voltage line.
